(19) United States
(12) Patent Application Publication
(10) Pub. No.: US 2026/0215199 A1
(43) Pub. Date: Jul. 23, 2026

(54) SUBSTRATE PROCESSING METHOD AND SUBSTRATE PROCESSING DEVICE

(71) Applicant: SCREEN Holdings Co., Ltd., Kyoto (JP)

(72) Inventors: Tetsuya EMOTO, Kyoto (JP); Atsuro EITOKU, Kyoto (JP); Toru ENDO, Kyoto (JP)

(21) Appl. No.: 19/141,032

(22) PCT Filed: Oct. 4, 2023
(86) PCT No.: PCT/JP2023/036183

§ 371 Date: Jun. 18, 2025

(30) Foreign Application Priority Data
Dec. 27, 2022 (JP) 2022-210950

(51) Int. Cl. H10P 72/00; H10P 72/76

(52) U.S. Cl. CPC H10P 72/0414; H10P 72/0602; H10P 72/7608; H10P 72/7618

(57) ABSTRACT

In a fully closed state where first and second chuck pins are in contact with an end surface of a horizontal substrate, supply of a sulfuric acid-containing liquid having a temperature higher than that of the substrate to the substrate is started and continued. The sulfuric liquid is supplied to the substrate in a first closed state where the first chuck pins are in contact with the end surface of the substrate. The liquid is supplied to the substrate in the fully closed state. The liquid is supplied to the substrate in a second closed state where the second chuck pins are in contact with the end surface of the substrate.

### RELATED APPLICATION

This application claims the benefit of priority to Japanese Patent Application No. 2022-210950 filed on Dec. 27, 2022, the entire contents of which are hereby incorporated herein by reference.

### TECHNICAL FIELD

The present invention relates to a substrate processing method and a substrate processing apparatus that process a substrate. The substrate includes a semiconductor wafer, a substrate for a FPD (Flat Panel Display) such as a liquid crystal display and an organic EL (electroluminescence) display, a substrate for an optical disc, a substrate for a magnetic disc, a substrate for a magneto-optical disc, a substrate for a photomask, a ceramic substrate, a substrate for a solar cell, and the like, for example.

### BACKGROUND ART

Patent Literature 1 discloses that the number of clamping members in contact with an end surface of a substrate is changed while an etching solution is supplied to the substrate. The supply of the etching solution to the substrate is started in a state where a first clamping member group including at least two clamping members clamps the substrate and the substrate is rotating. Thereafter, in a state where the first clamping member group clamps the substrate, a second clamping member group including at least two clamping members clamps the substrate. Then, in a state where the second clamping member group clamps the substrate, the first clamping member group is separated from the substrate.

### CITATION LIST

### Patent Literature

Patent Literature 1: JP 2004-111902 A

### SUMMARY OF INVENTION

### Technical Problem

Embodiments of the present invention provide a novel substrate processing method and substrate processing apparatus capable of supplying a sulfuric acid-containing liquid having a temperature higher than that of a substrate to the entire end surface of the substrate.

### Solution to Problem

An embodiment of the present invention provides a substrate processing method, including: starting and continuing supply of a sulfuric acid-containing liquid having a temperature higher than that of a horizontal substrate to the substrate while rotating the substrate in a fully closed state where a plurality of first chuck pins and a plurality of second chuck pins are in contact with an end surface of the substrate; supplying the sulfuric acid-containing liquid to the substrate while rotating the substrate in a first closed state where the plurality of first chuck pins are in contact with the end surface of the substrate and the plurality of second chuck pins are separated from the end surface of the substrate by separating the plurality of second chuck pins from the end surface of the substrate; supplying the sulfuric acid-containing liquid to the substrate while rotating the substrate in the fully closed state by bringing the plurality of second chuck pins into contact with the end surface of the substrate; and supplying the sulfuric acid-containing liquid to the substrate while rotating the substrate in a second closed state where the plurality of first chuck pins are separated from the end surface of the substrate and the plurality of second chuck pins are in contact with the end surface of the substrate by separating the plurality of first chuck pins from the end surface of the substrate.

According to this method, the sulfuric acid-containing liquid is supplied to the horizontal substrate while rotating the substrate in a state where at least one of the plurality of first chuck pins and the plurality of second chuck pins are in contact with the end surface of the substrate. Specifically, the supply of the sulfuric acid-containing liquid to the substrate is started in the fully closed state where the plurality of first chuck pins and the plurality of second chuck pins are in contact with the end surface of the substrate. Thereafter, the plurality of first chuck pins and the plurality of second chuck pins are switched to the first closed state where the plurality of first chuck pins are in contact with the end surface of the substrate and the plurality of second chuck pins are separated from the end surface of the substrate. Thereafter, the plurality of first chuck pins and the plurality of second chuck pins are switched to the fully closed state. Then, the plurality of first chuck pins and the plurality of second chuck pins are switched to the second closed state where the plurality of second chuck pins are in contact with the end surface of the substrate.

The sulfuric acid-containing liquid is a liquid having a temperature higher than the temperature of the substrate before the sulfuric acid-containing liquid is supplied. When the supply of the sulfuric acid-containing liquid to the substrate is started, the temperature of the substrate rises, and the temperature of the substrate is unevenly distributed. When a certain period of time elapses after the supply of the sulfuric acid-containing liquid is started, the temperature of the substrate is stabilized, and such uneven temperature distribution is eliminated or reduced. When the temperature of the substrate varies, the substrate is deformed. When the supply of the sulfuric acid-containing liquid to the substrate is started, both the plurality of first chuck pins and the plurality of second chuck pins are in contact with the end surface of the substrate. Therefore, it is possible to supply the sulfuric acid-containing liquid to the substrate while more reliably stabilizing the posture of the substrate as compared with a case where the supply of the sulfuric acid-containing liquid is started in a state where only the plurality of first chuck pins or only the plurality of second chuck pins are in contact with the end surface of the substrate.

After the supply of the sulfuric acid-containing liquid to the substrate is started, only the plurality of first chuck pins are brought into contact with the end surface of the substrate, and then only the plurality of second chuck pins are brought into contact with the end surface of the substrate. When the first chuck pin is separated from the end surface of the substrate, the sulfuric acid-containing liquid enters between the substrate and the first chuck pin, and is supplied to a portion included in the end surface of the substrate and being in contact with the first chuck pin. When the second chuck pin is separated from the end surface of the substrate, the sulfuric acid-containing liquid is also supplied to a portion included in the end surface of the substrate and being in contact with the second chuck pin. As a result, the sulfuric acid-containing liquid can be supplied to the entire end surface of the substrate, and the end surface of the substrate can be uniformly processed with the sulfuric acid-containing liquid.

In the embodiment, at least one of the following features may be added to the substrate processing method.

The substrate processing method further includes: supplying the sulfuric acid-containing liquid to the substrate while rotating the substrate in the fully closed state by bringing the plurality of first chuck pins into contact with the end surface of the substrate; and replacing the sulfuric acid-containing liquid in contact with the substrate with a replacement liquid having a temperature lower than that of the sulfuric acid-containing liquid while rotating the substrate in the fully closed state.

In this case, the plurality of first chuck pins and the plurality of second chuck pins are switched from a state where only the plurality of second chuck pins are in contact with the end surface of the substrate to a state where both the plurality of first chuck pins and the plurality of second chuck pins are in contact with the end surface of the substrate. In this state, the sulfuric acid-containing liquid in contact with the substrate is replaced with a replacement liquid. The replacement liquid is a liquid having a lower temperature than that of the sulfuric acid-containing liquid. When the supply of the replacement liquid to the substrate is started, the temperature of the substrate decreases, and the substrate is deformed. When the supply of the replacement liquid to the substrate is started, both the plurality of first chuck pins and the plurality of second chuck pins are brought into contact with the end surface of the substrate. Therefore, it is possible to supply the replacement liquid to the substrate while more reliably stabilizing the posture of the substrate as compared with a case where the supply of the replacement liquid is started in a state where only the plurality of first chuck pins or only the plurality of second chuck pins are in contact with the end surface of the substrate.

The first division step to the fifth division step may be a series of continuous steps in which a chemical liquid supply step of supplying the sulfuric acid-containing liquid to the substrate is divided into five in accordance with the states of the plurality of first chuck pins and the plurality of second chuck pins. The second division step may be a step continuous to the first division step. That is, when the first division step ends, the second division step may start without performing another step other than the second division step. The third division step may be a step continuous to the second division step. The same applies to the fourth and subsequent division steps.

A rotational speed of the substrate when the sulfuric acid-containing liquid in contact with the substrate is started to be replaced with the replacement liquid is higher than a rotational speed of the substrate in at least one of starting and continuing the supply of the sulfuric acid-containing liquid to the substrate while rotating the substrate in the fully closed state, supplying the sulfuric acid-containing liquid to the substrate while rotating the substrate in the first closed state, supplying the sulfuric acid-containing liquid to the substrate while rotating the substrate in the fully closed state and supplying the sulfuric acid-containing liquid to the substrate while rotating the substrate in the second closed state.

In this case, the replacement liquid is started to be supplied to the substrate in a state where the substrate is rotated at a higher speed than when the sulfuric acid-containing liquid is supplied to the substrate. As the rotational speed of the substrate increases, the force applied to the substrate also increases. Further, when the supply of the replacement liquid to the substrate is started, the temperature of the substrate decreases, and the substrate is deformed. When the supply of the replacement liquid to the substrate is started, both the plurality of first chuck pins and the plurality of second chuck pins are brought into contact with the end surface of the substrate. Therefore, it is possible to supply the replacement liquid to the substrate while more reliably stabilizing the posture of the substrate as compared with a case where the supply of the replacement liquid is started in a state where only the plurality of first chuck pins or only the plurality of second chuck pins are in contact with the end surface of the substrate.

The replacement liquid is hydrogen peroxide water having a temperature lower than that of the sulfuric acid-containing liquid.

In this case, the sulfuric acid-containing liquid in contact with the substrate is replaced with hydrogen peroxide water corresponding to the replacement liquid. The hydrogen peroxide water is a liquid having a lower temperature than that of the sulfuric acid-containing liquid. When hydrogen peroxide contained in the hydrogen peroxide water reacts with sulfuric acid contained in the sulfuric acid-containing liquid, heat is generated. Therefore, the temperature decrease of the substrate can be alleviated by the heat of reaction between sulfuric acid and hydrogen peroxide, and the rate at which the substrate deforms can be reduced. Accordingly, it is possible to supply hydrogen peroxide water corresponding to the replacement liquid to the substrate while more reliably stabilizing the posture of the substrate.

In the substrate processing method, starting and continuing the supply of the sulfuric acid-containing liquid to the substrate while rotating the substrate in the fully closed state, supplying the sulfuric acid-containing liquid to the substrate while rotating the substrate in the first closed state, supplying the sulfuric acid-containing liquid to the substrate while rotating the substrate in the fully closed state and supplying the sulfuric acid-containing liquid to the substrate while rotating the substrate in the second closed state are performed again after the sulfuric acid-containing liquid in contact with the substrate is replaced with the replacement liquid.

In this case, the sulfuric acid-containing liquid having a temperature higher than that of the substrate is supplied to the substrate, and then the replacement liquid having a temperature lower than that of the sulfuric acid-containing liquid is supplied to the substrate. Thereafter, the sulfuric acid-containing liquid is supplied to the substrate again. When the high-temperature sulfuric acid-containing liquid is continuously supplied to the substrate for a long time, members in contact with the substrate, such as the first chuck pin and the second chuck pin, have a high temperature. When the sulfuric acid-containing liquid is replaced with the low-temperature replacement liquid and then the sulfuric acid-containing liquid is supplied again, the period during which the temperature of the members in contact with the substrate is high can be shortened.

In the substrate processing method, at least one of switching from starting and continuing the supply of the sulfuric acid-containing liquid to the substrate while rotating the substrate in the fully closed state to supplying the sulfuric acid-containing liquid to the substrate while rotating the substrate in the first closed state, switching from supplying the sulfuric acid-containing liquid to the substrate while rotating the substrate in the first closed state to supplying the sulfuric acid-containing liquid to the substrate while rotating the substrate in the fully closed state, and switching from supplying the sulfuric acid-containing liquid to the substrate while rotating the substrate in the fully closed state to supplying the sulfuric acid-containing liquid to the substrate while rotating the substrate in the second closed state is performed while maintaining a constant rotational speed of the substrate.

In this case, the plurality of first chuck pins and the plurality of second chuck pins are switched between two of the fully closed state, the first closed state, and the second closed state while the rotational speed of the substrate is maintained constant. When the substrate is accelerated in the rotation direction, the force applied to the substrate increases. When the rotational speed of the substrate is constant, the fluctuation of the force applied to the substrate with the rotation of the substrate is small. In such a state, the states of the plurality of first chuck pins and the plurality of second chuck pins are switched. Accordingly, it is possible to supply the sulfuric acid-containing liquid to the substrate while more reliably stabilizing the posture of the substrate.

In the substrate processing method, at least one of switching from starting and continuing the supply of the sulfuric acid-containing liquid to the substrate while rotating the substrate in the fully closed state to Supplying the sulfuric acid-containing liquid to the substrate while rotating the substrate in the first closed state and switching from supplying the sulfuric acid-containing liquid to the substrate while rotating the substrate in the fully closed state to supplying the sulfuric acid-containing liquid to the substrate while rotating the substrate in the second closed state is performed while maintaining a constant rotational speed of the substrate.

In this case, the plurality of first chuck pins or the plurality of second chuck pins are separated from the end surface of the substrate while maintaining the constant rotational speed of the substrate. When the plurality of first chuck pins or the plurality of second chuck pins are separated from the end surface of the substrate, the force to hold the substrate is weakened. If the rotational speed of the substrate is kept constant at such a time, the states of the plurality of first chuck pins and the plurality of second chuck pins can be switched while more reliably stabilizing the posture of the substrate.

The starting and continuing the supply of the sulfuric acid-containing liquid to the substrate while rotating the substrate in the fully closed state includes starting supply of the sulfuric acid-containing liquid to the substrate while rotating the substrate in a state where the plurality of first chuck pins and the plurality of second chuck pins are in contact with the end surface of the substrate and the liquid is not in contact with the substrate.

In this case, the sulfuric acid-containing liquid is supplied to the substrate that is not in contact with the liquid and is in contact with a tangible object such as the first chuck pin and air. When the sulfuric acid-containing liquid is supplied to the substrate to which the liquid is attached, the heat of the sulfuric acid-containing liquid is also transmitted to the liquid attached to the substrate, so that the temperature rise of the substrate is alleviated. When the sulfuric acid-containing liquid is supplied to the substrate to which no liquid is attached, the temperature rise of the substrate increases as compared with the above case. Therefore, when the sulfuric acid-containing liquid is supplied to the substrate not in contact with the liquid, by bringing both the plurality of first chuck pins and the plurality of second chuck pins into contact with the end surface of the substrate, it is possible to supply the sulfuric acid-containing liquid to the substrate while more reliably stabilizing the posture of the substrate.

A period of starting and continuing the supply of the sulfuric acid-containing liquid to the substrate while rotating the substrate in the fully closed state is shorter than a period of supplying the sulfuric acid-containing liquid to the substrate while rotating the substrate in the first closed state and shorter than a period of supplying the sulfuric acid-containing liquid to the substrate while rotating the substrate in the second closed state.

In this case, the period during which both the plurality of first chuck pins and the plurality of second chuck pins are in contact with the end surface of the substrate at the start of supply of the sulfuric acid-containing liquid is made shorter than the period during which only the plurality of first chuck pins or only the plurality of second chuck pins are in contact with the end surface of the substrate. In other words, the period during which the plurality of first chuck pins or the plurality of second chuck pins are separated from the end surface of the substrate is lengthened. Thereby, it is possible to lengthen the period during which the sulfuric acid-containing liquid is supplied to the portion in contact with the first chuck pin or the second chuck pin on the end surface of the substrate.

The period of starting and continuing the supply of the sulfuric acid-containing liquid to the substrate while rotating the substrate in the fully closed state is longer than the period of supplying the sulfuric acid-containing liquid to the substrate while rotating the substrate in the fully closed state.

In this case, the period of the fully closed state at the start of the supply of the sulfuric acid-containing liquid is made longer than the period of the fully closed state during the supply of the sulfuric acid-containing liquid. Since the period of the fully closed state at the start of supply of the sulfuric acid-containing liquid is long, the plurality of first chuck pins and the plurality of second chuck pins can be switched from the fully closed state to the first closed state in a state where the rate of change in the temperature of the substrate is small. Furthermore, since the period of the fully closed state during the supply of the sulfuric acid-containing liquid is short, that is, the period until the plurality of first chuck pins and the plurality of second chuck pins are switched from the first closed state to the second closed state is short, the period during which the sulfuric acid-containing liquid is supplied to the portion in contact with the first chuck pins or the second chuck pins on the end surface of the substrate can be lengthened.

Another embodiment of the present invention provides a substrate processing apparatus, including: a plurality of first chuck pins that hold a horizontal substrate by coming into contact with an end surface of the substrate; a plurality of second chuck pins that hold the substrate by coming into in contact with the end surface of the substrate; a first actuator that moves each of the plurality of first chuck pins between an open position where the first chuck pin is separated from the end surface of the substrate and a closed position where the first chuck pin is in contact with the end surface of the substrate; a second actuator that moves each of the plurality of second chuck pins between an open position where the second chuck pin is separated from the end surface of the substrate and a closed position where the second chuck pin is in contact with the end surface of the substrate; an electric motor that rotates the substrate held by at least one of the plurality of first chuck pins and the plurality of second chuck pins; a nozzle that supplies a sulfuric acid-containing liquid having a temperature higher than that of the substrate to the substrate held by at least one of the plurality of first chuck pins and the plurality of second chuck pins; a valve that switches between a supply execution state where the supply of the sulfuric acid-containing liquid to the nozzle is performed and a supply stop state where the supply of the sulfuric acid-containing liquid to the nozzle is stopped; and a controller that controls the first actuator, the second actuator, the electric motor, and the valve,

The controller executes: starting and continuing supply of the sulfuric acid-containing liquid to the substrate while rotating the substrate in a fully closed state where the plurality of first chuck pins and the plurality of second chuck pins are in contact with the end surface of the substrate; supplying the sulfuric acid-containing liquid to the substrate while rotating the substrate in a first closed state where the plurality of first chuck pins are in contact with the end surface of the substrate and the plurality of second chuck pins are separated from the end surface of the substrate by separating the plurality of second chuck pins from the end surface of the substrate; supplying the sulfuric acid-containing liquid to the substrate while rotating the substrate in the fully closed state by bringing the plurality of second chuck pins into contact with the end surface of the substrate; and supplying the sulfuric acid-containing liquid to the substrate while rotating the substrate in a second closed state where the plurality of first chuck pins are separated from the end surface of the substrate and the plurality of second chuck pins are in contact with the end surface of the substrate by separating the plurality of first chuck pins from the end surface of the substrate. According to this apparatus, the same advantages as the above-described substrate processing method can be obtained. At least one of the above-described features regarding the substrate processing method may be added to the substrate processing apparatus.

The above and other objects, features, and advantages of the present invention will become more apparent from the following detailed description of the embodiments with reference to the attached drawings.

### BRIEF DESCRIPTION OF DRAWINGS

FIG. 1A a schematic plan view showing a layout of a substrate processing apparatus according to an embodiment of the present invention.

FIG. 1B a schematic cross-sectional view showing a vertical cross-section of the substrate processing apparatus taken along line IB-IB shown in FIG. 1A.

FIG. 2A a schematic view of an interior of a processing unit as viewed horizontally.

FIG. 2B a schematic plan view showing the interior of the processing unit.

FIG. 3 a schematic view of a sulfuric acid supply system to supply sulfuric acid to a chemical liquid nozzle.

FIG. 4 a plan view of a spin chuck.

FIG. 5A and FIG. 5B schematic views of chuck pins positioned at an open position and a closed position as viewed horizontally.

FIG. 6A, FIG. 6B and FIG. 6C schematic plan views showing a plurality of chuck pins in a first closed state, a second closed state, and a fully closed state.

FIG. 7 a block diagram showing an electrical arrangement of the substrate processing apparatus.

FIG. 8 a process chart for describing one example of substrate processing by the substrate processing apparatus.

FIG. 9 a diagram for describing the number of chuck pins in contact with an end surface of a substrate when a processing liquid such as SPM is supplied to the substrate.

### DESCRIPTION OF EMBODIMENTS

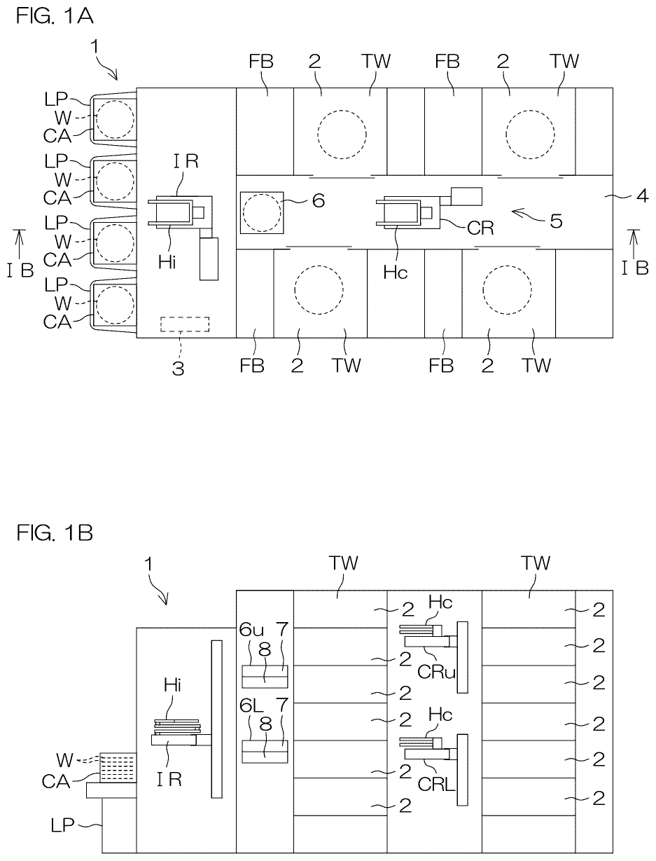

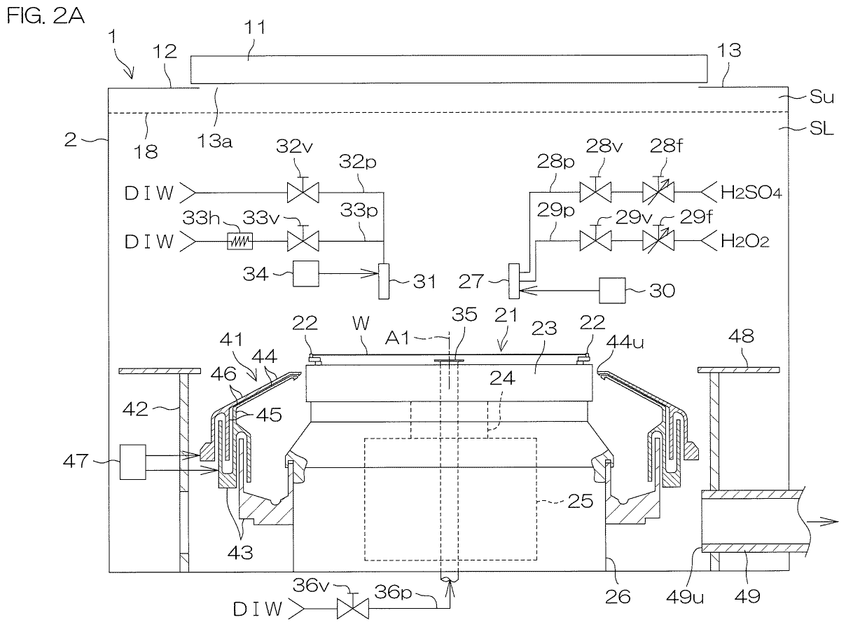

FIG. 1A is a schematic plan view showing a layout of a substrate processing apparatus 1 according to an embodiment of the present invention. FIG. 1B is a schematic cross-sectional view showing a vertical cross-section of the substrate processing apparatus 1 taken along line IB-IB shown in FIG. 1A.

The substrate processing apparatus 1 is a single substrate processing type apparatus that processes disk-shaped substrates W such as semiconductor wafers one by one. As shown in FIG. 1A, the substrate processing apparatus 1 includes a load port LP that supports a carrier CA housing a plurality of substrates W, a processing unit 2 that processes the substrate W transferred from the carrier CA on the load port LP with a processing fluid such as a processing liquid or a processing gas, a transfer system 5 that transfers the substrate W between the carrier CA on the load port LP and the processing unit 2, and a controller 3 that controls the substrate processing apparatus 1. FIG. 1A shows an example where a plurality of load ports LP and a plurality of processing units 2 are provided in the substrate processing apparatus 1.

The plurality of processing units 2 form a plurality of towers TW. FIG. 1A shows an example where four towers TW are formed. Half of a plurality of towers TW are disposed at a right side f a transfer passage 4 of rectilinear shape in a plan view and the remaining half of the plurality of towers TW are disposed at a left side of the transfer passage 4. As shown in FIG. 1B, each tower TW includes a plurality of processing units 2 that are stacked one above the other. In the present example, each tower TW includes six processing units 2 that are stacked one above the other. Therefore, 24 processing units 2 are provided in the substrate processing apparatus 1.

The processing units 2 at upper sides of all towers TW constitute an upper processing unit group and the processing units 2 at lower sides of all towers TW constitute a lower processing unit group. If the number of processing units 2 constituting a single tower TW is an odd number, the processing unit 2 at the middle may belong to either of the upper processing unit group and the lower processing unit group. In the example shown in FIGS. 1A and 1B, 12 processing units 2 at the upper side constitute the upper processing unit group and 12 processing units 2 at the lower side constitute the lower processing unit group.

As shown in FIG. 1A, the transfer system 5 includes a relay base 6 on which a substrate W transferred between the carrier CA on the load port LP and the processing unit 2 is placed temporarily, an indexer robot IR that transfers the substrate W between the carrier CA on the load port LP and the relay base 6, and a center robot CR that transfers the substrate W between the relay base 6 and the processing unit 2.

The relay base 6 is disposed between the indexer robot IR and the center robot CR in a plan view. As shown in FIG. 1B, the relay base 6 includes an upper relay base 6u and a lower relay base 6L overlapping each other in a plan view. The upper relay base 6u is disposed above the lower relay base 6L. The upper relay base 6u temporarily holds the substrate W that is being transferred between the upper processing unit group and the carrier CA. The lower relay base 6L temporarily holds the substrate W that is being transferred between the lower processing unit group and the carrier CA.

Each of the upper relay base 6u and the lower relay base 6L includes a non-processed relay base 7 on which a non-processed substrate W is placed and a processed relay base 8 on which a processed substrate W is placed. The non-processed relay base 7 and the processed relay base 8 overlap each other in a plan view. The non-processed relay base 7 is disposed above the processed relay base 8. In at least one of the upper relay base 6u and the lower relay base 6L, the non-processed relay base 7 may be disposed below the processed relay base 8.

The non-processed relay base 7 and the processed relay base 8 both include a plurality of supporting portions that support a plurality of substrates W horizontally such as to overlap one above the other. Each supporting portion may be a plurality of pins that contact a lower surface of the substrate W or may be a pair of rails that extend horizontally at a right side and a left side of the substrate W. The substrate W can enter inside the non-processed relay base 7 from either of the indexer robot IR side and the center robot CR side and can enter inside the processed relay base 8 from either of the indexer robot IR side and the center robot CR side.

The indexer robot IR is disposed between the relay base 6 and the load port LP in a plan view. The indexer robot IR includes one or more hands Hi that support the substrates W horizontally. Each hand Hi is movable in parallel in both the horizontal direction and the vertical direction. The hand Hi is rotatable by not less than 180 degrees around a vertical straight line. The hand Hi can perform carry-in and carry-out of the substrate W with respect to any carrier CA on the plurality of load ports LP and can also perform carry-in and carry-out of the substrate W with respect to any of the non-processed relay bases 7 and processed relay bases 8.

As shown in FIG. 1B, the center robot CR includes an upper center robot CRu that transfers the substrate W between the upper relay base 6u and the upper processing unit group and a lower center robot CRL that transfers the substrate W between the lower relay base 6L and the lower processing unit group. The upper center robot CRu is disposed higher than the lower center robot CRL. The upper center robot CRu and the lower center robot CRL are disposed in the transfer passage 4 formed between the plurality of towers TW.

The upper center robot CRu and the lower center robot CRL both include one or more hands Hc that support the substrate W horizontally. Each hand Hc is movable in parallel in both the horizontal direction and the vertical direction. The hand Hc is rotatable by not less than 180 degrees around a vertical straight line.

The hand Hc of the upper center robot CRu can perform carry-in and carry-out of the substrate W with respect to any processing unit 2 belonging to the upper processing unit group and can perform carry-in and carry-out of the substrate W with respect to the non-processed relay base 7 and the processed relay base 8 of the upper relay base 6u. The hand Hc of the lower center robot CRL can perform carry-in and carry-out of the substrate W with respect to any processing unit 2 belonging to the lower processing unit group and can perform carry-in and carry-out of the substrate W with respect to the non-processed relay base 7 and the processed relay base 8 of the upper relay base 6L.

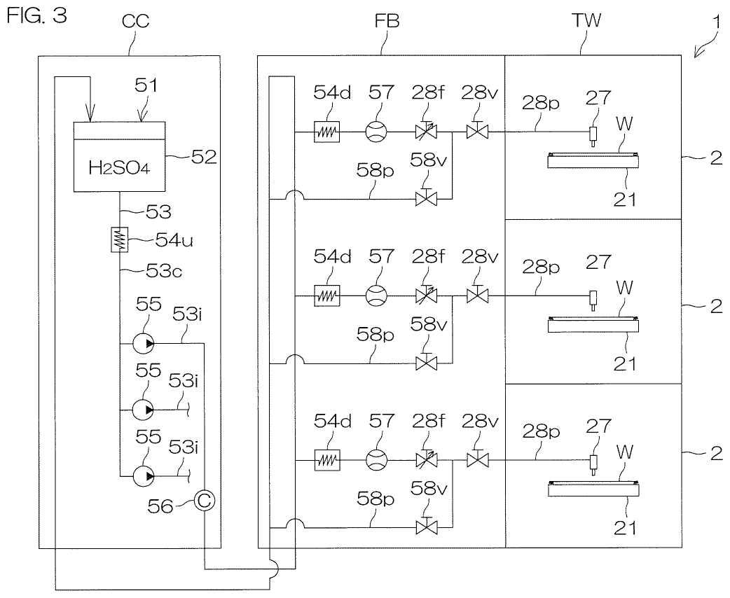

As shown in FIG. 1A, the substrate processing apparatus 1 includes a plurality of fluid boxes FB that accommodate fluid devices such as valves. One fluid box FB is provided for each tower TW. Sulfuric acid in a cabinet CC (see FIG. 3) to be described later is supplied to all the processing units 2 included in the tower TW corresponding to the relevant fluid box FB via any of the fluid boxes FB.

Next, the processing unit 2 will be described.

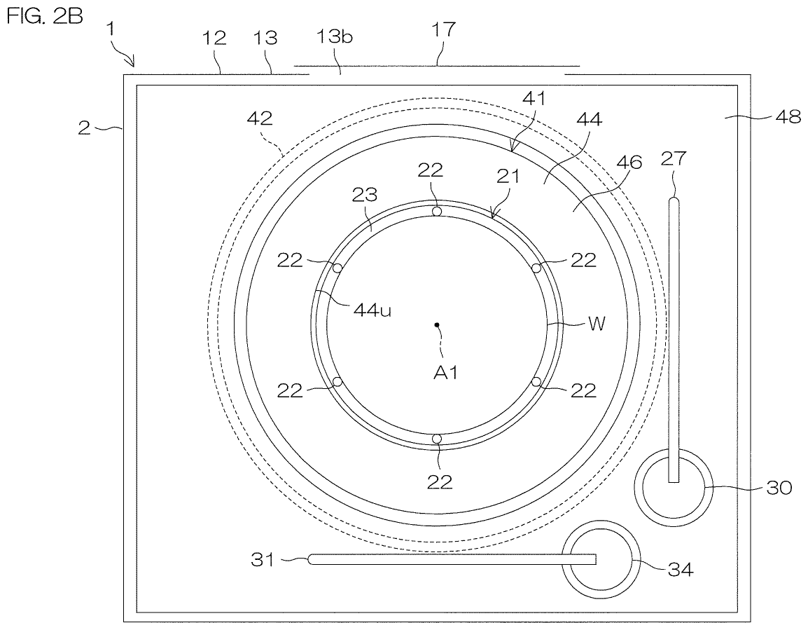

FIG. 2A is a schematic view of an interior of the processing unit 2 as viewed horizontally. FIG. 2B is a schematic plan view showing the interior of the processing unit 2. DIW in FIG. 2A represents pure water.

As shown in FIG. 2A, the processing unit 2 includes a box-shaped chamber 12 having an interior space, a spin chuck 21 that rotates one substrate W around a vertical rotational axis A1 passing through the central portion of the substrate W while holding it horizontally in the chamber 12, and a plurality of nozzles that supply the substrate W held by the spin chuck 21 with the processing fluid such as the processing liquid or the processing gas.

As shown in FIG. 2B, the chamber 12 has a partition wall 13 of box shape that is provided with a carry-in/carry-out port 13b through which the substrate W transferred by the center robot CR (see FIG. 1A) passes and a shutter 17 that opens and closes the carry-in/carry-out port 13b. As shown in FIG. 2A, the chamber 12 further includes a rectifying plate 18 that is disposed below an air blowing port 13a that opens at a ceiling surface of the partition wall 13. An FFU 11 (fan filter unit 11) that feeds clean air (air filtered by a filter) is disposed above the air blowing port 13a. The air blowing port 13a is provided at an upper end portion of the chamber 12 and an exhaust duct 49 is disposed at a lower end portion of the chamber 12. An upstream end 49u of the exhaust duct 49 is disposed inside the chamber 12 and a downstream end of the exhaust duct 49 is disposed outside the chamber 12.

The rectifying plate 18 partitions an internal space of the chamber 12 into an upper space Su above the rectifying plate 18 and a lower space SL below the rectifying plate 18. The upper space Su between the ceiling surface of the partition wall 13 and an upper surface of the rectifying plate 18 is a dispersion space in which the clean air disperses. The lower space SL between a lower surface of the rectifying plate 18 and a floor surface of the partition wall 13 is a processing space in which processing of the substrate W is performed. A spin chuck 21 is disposed in the lower space SL. A distance in the vertical direction from the floor surface of the partition wall 13 to the lower surface of the rectifying plate 18 is longer than a distance in the vertical direction from the upper surface of the rectifying plate 18 to the ceiling surface of the partition wall 13.

The FFU 11 feeds clean air into the upper space Su via the air blowing port 13a. The clean air supplied into the upper space Su hits the rectifying plate 18 and disperses in the upper space Su. The clean air inside the upper space Su passes through a plurality of penetrating holes that penetrate up and down through the rectifying plate 18 and flows downward from an entire area of the rectifying plate 18. The clean air supplied into the lower space SL is sucked into the exhaust duct 49 and is released from the chamber 12. A uniform descending flow (down flow) of clean air that flows downward from the rectifying plate 18 is thereby formed in the lower space SL. The processing of the substrate W is performed in a state where the descending flow of clean air is formed.

The spin chuck 21 includes a plurality of chuck pins 22 that clamp the substrate W horizontally and a disk-shaped spin base 23 that supports the plurality of chuck pins 22. The spin chuck 21 further includes a spin shaft 24 that extends downward from the central portion of the spin base 23, an electric motor 25 that rotates the spin shaft 24 to rotate the plurality of chuck pins 22 and the spin base 23, and a chuck housing 26 that surrounds the electric motor 25.

The spin base 23 includes an upper surface of circular shape that is disposed below the substrate W and an outer circumferential surface of circular cylindrical shape that extends downward from an outer circumference of the upper surface of the spin base 23. The upper surface of the spin base 23 is parallel to the lower surface of the substrate W. The upper surface of the spin base 23 is separated from the lower surface of the substrate W. The upper surface of the spin base 23 is concentric to the substrate W. An outer diameter of the upper surface of the spin base 23 is greater than an outer diameter of the substrate W. The chuck pins 22 project upward from an outer circumferential portion of the upper surface of the spin base 23.

As shown in FIG. 2A, the plurality of nozzles include a chemical liquid nozzle 27 that discharges a chemical liquid toward the upper surface of the substrate W, a rinse liquid nozzle 31 that discharges a rinse liquid toward the upper surface of the substrate W, and a lower surface nozzle 35 that discharges a processing liquid toward the lower surface of the substrate W. FIG. 2A shows an example in which at least one of sulfuric acid and hydrogen peroxide water is discharged from the chemical liquid nozzle 27, and pure water (deionized water (DIW) ) or hot water (pure water having a temperature higher than room temperature) is discharged from the rinse liquid nozzle 31 and the lower surface nozzle 35.

The chemical liquid may be sulfuric acid or hydrogen peroxide water, or may be a mixed liquid of sulfuric acid-hydrogen peroxide mixture (SPM). The chemical liquid may be a liquid other than at least one of sulfuric acid and hydrogen peroxide water. Specifically, the chemical liquid may be a liquid that includes at least one among sulfuric acid, nitric acid, hydrochloric acid, hydrofluoric acid, phosphoric acid, acetic acid, ammonia water, hydrogen peroxide water, organic acids (for example, citric acid, oxalic acid, etc.), organic alkalis (for example, TMAH: tetramethylammonium hydroxide, etc.), surfactants, and corrosion inhibitors, or may be a liquid other than this. The temperature of the chemical liquid may be room temperature (e. g., 20 to 30° C.), or may be higher or lower than room temperature.

The rinse liquid may be a liquid other than pure water. Specifically, the rinse liquid may be a liquid that includes at least one among pure water, carbonated water, electrolyzed ion water, hydrogen water, ozone water, an aqueous hydrochloric acid solution of dilute concentration (for example, approximately 10 to 100 ppm), and an ammonia water of dilute concentration (for example, approximately 10 to 100 ppm) or may be a liquid other than this. The temperature of the rinse liquid may be room temperature, or may be higher or lower than room temperature.

The chemical liquid nozzle 27 may be a scan nozzle that moves a collision position of the processing liquid with respect to the substrate W in a radial direction of the substrate W within the upper surface of the substrate W, or may be a fixed nozzle that cannot move the collision position of the processing liquid with respect to the substrate W in the radial direction of the substrate W. The same applies to other nozzles. FIG. 2A shows an example where the chemical liquid nozzle 27 and the rinse liquid nozzle 31 are scan nozzles and the lower surface nozzle 35 is a fixed nozzle.

The processing unit 2 includes a nozzle moving unit that moves one or more scan nozzles horizontally. A single nozzle moving unit that is connected to two or more scan nozzles may be provided or a single nozzle moving unit may be provided for each single scan nozzle. FIG. 2B shows an example where the chemical liquid nozzle 27 is connected to a first nozzle moving unit 30, and the rinse liquid nozzle 31 is connected to a second nozzle moving unit 34.

FIG. 2B shows an example where each of the first nozzle moving unit 30 and the second nozzle moving unit 34 is a swinging unit that moves one or more of the scan nozzles horizontally along a path of arcuate shape in a plan view. A radius of the path of arcuate shape is large and therefore, the swinging unit moves one or more of the scan nozzles horizontally along a path that can be regarded as being a straight line in a plan view. At least one of the first nozzle moving unit 30 and the second nozzle moving unit 34 may be a slide unit that moves one or more of the scan nozzles horizontally along a path of rectilinear shape in a plan view.

As shown in FIG. 2A, the chemical liquid nozzle 27 is connected to a sulfuric acid piping 28p that guides sulfuric acid toward the chemical liquid nozzle 27 and a hydrogen peroxide water piping 29p that guides hydrogen peroxide water toward the chemical liquid nozzle 27. A sulfuric acid valve 28v and a flow control valve 28f are mounted on the sulfuric acid piping 28p. A hydrogen peroxide water valve 29v and a flow control valve 29f are interposed in the hydrogen peroxide water piping 29p.

Although not shown, the sulfuric acid valve 28v includes a valve body provided with an annular valve seat through which a processing liquid passes, a valve element that can move with respect to the valve seat, and an actuator that moves the valve element between a closed position where the valve element contacts the valve seat and an open position where the valve element is away from the valve seat. The same applies to other valves. The actuator may be a pneumatic actuator or an electric actuator, or may be an actuator other than these. The controller 3 opens and closes the sulfuric acid valve 28v by controlling the actuator.

When the sulfuric acid valve 28v is opened, sulfuric acid is supplied from the sulfuric acid piping 28p to the chemical liquid nozzle 27 at a flow rate corresponding to an opening degree of the flow control valve 28f. When the hydrogen peroxide water valve 29v is opened, the hydrogen peroxide water is supplied from the hydrogen peroxide water piping 29p to the chemical liquid nozzle 27 at a flow rate corresponding to an opening degree of the flow control valve 29f. When the sulfuric acid valve 28v and the hydrogen peroxide water valve 29v are opened, sulfuric acid and the hydrogen peroxide water become mixed together and the SPM is formed. The SPM is continuously discharged downward from the chemical liquid nozzle 27. When the sulfuric acid valve 28v is closed while the chemical liquid nozzle 27 is discharging the SPM, only hydrogen peroxide water is continuously discharged downward from the chemical liquid nozzle 27.

The temperature of the SPM discharged from the chemical liquid nozzle 27 is, for example, higher than 100° C. The temperature of the SPM may be 200° C. or higher. The temperature of the sulfuric acid before being mixed with the hydrogen peroxide water is, for example, higher than 100° C. The temperature of the sulfuric acid may be 150° C. or higher. The temperature of the hydrogen peroxide water before being mixed with the sulfuric acid is, for example, room temperature (for example, 20 to 30° C.). The temperature of the hydrogen peroxide water before being mixed with sulfuric acid may be higher than room temperature and lower than the temperature of sulfuric acid before being mixed with the hydrogen peroxide water.

The first nozzle moving unit 30 horizontally moves the chemical liquid nozzle 27 between a processing position where the chemical liquid nozzle 27 overlaps the substrate W in a plan view and a standby position where the chemical liquid nozzle 27 does not overlap the substrate W in a plan view. When the SPM is discharged while the chemical liquid nozzle 27 is disposed at the processing position, the discharged SPM is supplied to the upper surface of the substrate W. Even when the SPM is discharged while the chemical liquid nozzle 27 is disposed at the standby position, the discharged SPM is not supplied to the substrate W. The same applies when the chemical liquid nozzle 27 discharges a chemical liquid other than the SPM such as the hydrogen peroxide water.

The rinse liquid nozzle 31 is connected to a pure water piping 32p that guides pure water toward the rinse liquid nozzle 31 and a hot water piping 33p that guides hot water toward the rinse liquid nozzle 31. A pure water valve 32v is attached to the pure water piping 32p. A hot water valve 33v and a heater 33h are attached to the hot water piping 33p. The heater 33h heats pure water at room temperature flowing through the hot water piping 33p toward the rinse liquid nozzle 31 to a temperature higher than room temperature.

When the hot water valve 33v is opened, hot water is supplied from the hot water piping 33p to the rinse liquid nozzle 31, and is continuously discharged downward from the rinse liquid nozzle 31. The same applies when the pure water valve 32v is opened. The second nozzle moving unit 34 horizontally moves the rinse liquid nozzle 31 between a processing position where the rinse liquid nozzle 31 overlaps the substrate W in a plan view and a standby position where the rinse liquid nozzle 31 does not overlap the substrate W in a plan view.

The lower surface nozzle 35 is connected to a rinse liquid piping 36p that guides the rinse liquid toward the lower surface nozzle 35. A rinse liquid valve 36v is attached to the rinse liquid piping 36p. When the rinse liquid valve 36v is opened, the rinse liquid is supplied from the rinse liquid piping 36p to the lower surface nozzle 35, and is continuously discharged downward from the lower surface nozzle 35. When the substrate W is held by the spin chuck 21, a discharge port of the lower surface nozzle 35 is disposed between the upper surface of the spin base 23 and the lower surface of the substrate W, and vertically faces a central portion of the lower surface of the substrate W. When the lower surface nozzle 35 discharges the processing liquid such as the rinse liquid, the discharged processing liquid collides with the central portion of the lower surface of the substrate W.

The processing unit 2 includes a tubular processing cup 41 that receives the processing liquid scattered outward from the spin chuck 21 and the substrate W. The processing cup 41 surrounds the spin chuck 21 around the rotational axis A1 of the substrate W within the chamber 12. The processing cup 41 includes a plurality of guards 44 that receive the processing liquid scattered outward from the spin chuck 21 and the substrate W, and a plurality of cup 43 that receive the processing liquid guided downward by the plurality of guards 44. FIG. 2A shows an example where two guards 44 and two cups 43 are provided and the outermost cup 43 is integral to the second guard 44 from the top.

The guard 44 includes a cylindrical portion 45 surrounding the spin chuck 21, and a toric ceiling portion 46 extending upward obliquely from the upper end portion of the cylindrical portion 45 toward the rotational axis A1. The plurality of ceiling portions 46 overlap each other vertically, and the plurality of cylindrical portions 45 are concentrically disposed. The toric upper end of the ceiling portion 46 corresponds to the upper end 44u of the guard 44 surrounding the substrate W and the spin base 23 in a plan view. The plurality of cup 43 are disposed under the plurality of cylindrical portions 45, respectively. The cup 43 forms an annular groove that receives the processing liquid guided downward by the guard 44.

In addition to the plurality of guards 44 and the plurality of cups 43, the processing cup 41 includes a cylindrical outer wall 42 Surrounding the plurality of guards 44 and the plurality of cups 43. The cylindrical outer wall 42 surrounds a guard 44 which, among all the guards 44, is positioned at the outermost side, across an interval in a radial direction. The cylindrical outer wall 42 extends upward from the floor surface of the chamber 12. As described later, the guard 44 is movable up and down between an upper position and a lower position. An upper end of the cylindrical outer wall 42 is disposed below the upper end 44u of the guard 44 located at the upper position.

The processing unit 2 includes a guard raising/lowering unit 47 that individually raises and lowers the plurality of guards 44. The guard raising/lowering unit 47 positions the guard 44 at any position within a range from an upper position to a lower position. FIG. 2A shows a state where two guards 44 are disposed at the lower position. The upper position is a position where the upper end 44u of the guard 44 is disposed above a holding position where the substrate W held by the spin chuck 21 is positioned. The lower position is a position where the upper end 44u of the guard 44 is disposed below the holding position.

When the processing liquid is supplied to the substrate W that is rotating, at least one of the guards 44 is disposed at the upper position. When the processing liquid is supplied to the substrate W in this state, the processing liquid is spun off outward from the substrate W. The spun-off processing liquid collides with an inner surface of the guard 44 that opposes the substrate W horizontally and is guided into the cup 43 corresponding to the guard 44. The processing liquid discharged from the substrate W is thereby collected in the cup 43.

The processing unit 2 includes a partitioning plate 48 disposed along a horizontal plane in a space around the plurality of guards 44 located at the upper position. The partitioning plate 48 surrounds the plurality of guards 44. An inner edge of the partitioning plate 48 is horizontally separated from the plurality of guards 44. An outer edge of the partitioning plate 48 is horizontally separated from an inner circumferential surface of the chamber 12 (inner circumferential surface of the partition wall 13 surrounding the substrate W). The partitioning plate 48 is disposed above the cylindrical outer wall 42. The partitioning plate 48 is disposed on the cylindrical outer wall 42. The partitioning plate 48 is disposed below the upper end 44u of the guard 44 located at the upper position.

Next, a sulfuric acid supply system 51 will be described.

FIG. 3 is a schematic view of the sulfuric acid supply system 51 to supply sulfuric acid to the chemical liquid nozzle 27.

The sulfuric acid supply system 51 includes a sulfuric acid tank 52 that stores sulfuric acid to be supplied to the chemical liquid nozzle 27, and a circulation piping 53 that circulates the sulfuric acid supplied from the sulfuric acid tank 52. The circulation piping 53 includes a common piping 53c that guides the sulfuric acid supplied from the sulfuric acid tank 52 to the downstream and a plurality of individual piping 53i that guide the sulfuric acid having passed through the common piping 53c to the downstream.

The plurality of individual piping 53i are branched from the common piping 53c. One individual piping 53i is provided for each tower TW formed by the plurality of processing units 2. The sulfuric acid guided by the individual piping 53i is supplied to the plurality of processing units 2 constituting the same tower TW. The plurality of sulfuric acid piping 28p corresponding to the plurality of processing units 2 constituting the same tower TW are connected to the same individual piping 531. The individual piping 53i passes through the fluid box FB and returns to the sulfuric acid tank 52.

An upstream end of the individual piping 53i is connected to a downstream end of the common piping 53c. A downstream end of the individual piping 53i is connected to the sulfuric acid tank 52. An upstream end of the common piping 53c is also connected to the sulfuric acid tank 52. The sulfuric acid supply system 51 includes a circulation pump 55 that transfers the sulfuric acid in the sulfuric acid tank 52 to the circulation piping 53, and a concentration meter 56 that measures the concentration of sulfuric acid. FIG. 3 shows an example in which the concentration meter 56 measures the concentration of sulfuric acid flowing in the individual piping 53i. The circulating sulfuric acid is supplied from the sulfuric acid tank 52 to the common piping 53c, and returns to the sulfuric acid tank 52 through one of the individual piping 53i.

FIG. 3 shows an example in which the sulfuric acid tank 52 is disposed in the cabinet CC, and the cabinet CC is disposed on the floor on which the substrate processing apparatus 1 is installed. The sulfuric acid tank 52 may be disposed outside the cabinet CC or may be disposed under the floor on which the substrate processing apparatus 1 is installed. The sulfuric acid tank 52 may be disposed in the substrate processing apparatus 1. All of the sulfuric acid supply system may be a portion of the substrate processing apparatus 1, or only a portion of the sulfuric acid supply system 51 may be a portion of the substrate processing apparatus 1. FIG. 3 shows an example in which only the plurality of individual piping 53i and a portion downstream thereof in the sulfuric acid supply system 51 are a portion of the substrate processing apparatus 1.

The sulfuric acid supply system 51 includes a flowmeter 57 that measures the flow rate of sulfuric acid flowing downstream in the sulfuric acid piping 28p, a return piping 58p that returns the sulfuric acid flowing downstream in the sulfuric acid piping 28p to the individual piping 53i, and a return valve 58v that switches between an open state where the sulfuric acid flows from the sulfuric acid piping 28p to the return piping 58p and a closed state where the sulfuric acid does not flow from the sulfuric acid piping 28p to the return piping 58p. The return piping 58p is branched from the sulfuric acid piping 28p upstream of the sulfuric acid valve 28v. An upstream end of the return piping 58p is connected to the sulfuric acid piping 28p. A downstream end of the return piping 58p is connected to the individual piping 53i in the fluid box FB.

When both the sulfuric acid valve 28v and the return valve 58v are closed, the sulfuric acid in the individual piping 53i does not flow into the sulfuric acid piping 28p. When the sulfuric acid valve 28v is opened and the return valve 58v is closed, the sulfuric acid in the individual piping 53i flows into the sulfuric acid piping 28p and is supplied to the chemical liquid nozzle 27. When the sulfuric acid valve 28v is closed and the return valve 58v is opened, the sulfuric acid in the individual piping 53i flows into the sulfuric acid piping 28p and is supplied from the sulfuric acid piping 28p to the return piping 58p. The sulfuric acid in the return piping 58p returns to the sulfuric acid tank 52 via the individual piping 531.

The sulfuric acid supply system 51 includes one or more heaters that heat sulfuric acid on a path from the sulfuric acid tank 52 to the chemical liquid nozzle 27. FIG. 3 shows an example in which one upstream heater 54u and a plurality of downstream heaters 54d are provided. In this example, the upstream heater 54u is attached to the common piping 53c, and the downstream heater 54d is attached to the sulfuric acid piping 28p upstream of a connection position of the sulfuric acid piping 28p and the return piping 58p. One downstream heater 54d is provided for each sulfuric acid piping 28p. The sulfuric acid in the sulfuric acid tank 52 returns to the sulfuric acid tank 52 after being heated by the upstream heater 54u or both the upstream heater 54u and the downstream heater 54d. Alternatively, the sulfuric acid in the sulfuric acid tank 52 is supplied to the chemical liquid nozzle 27 after being heated by both the upstream heater 54u and the downstream heater 54d.

Next, the chuck pin 22 will be described.

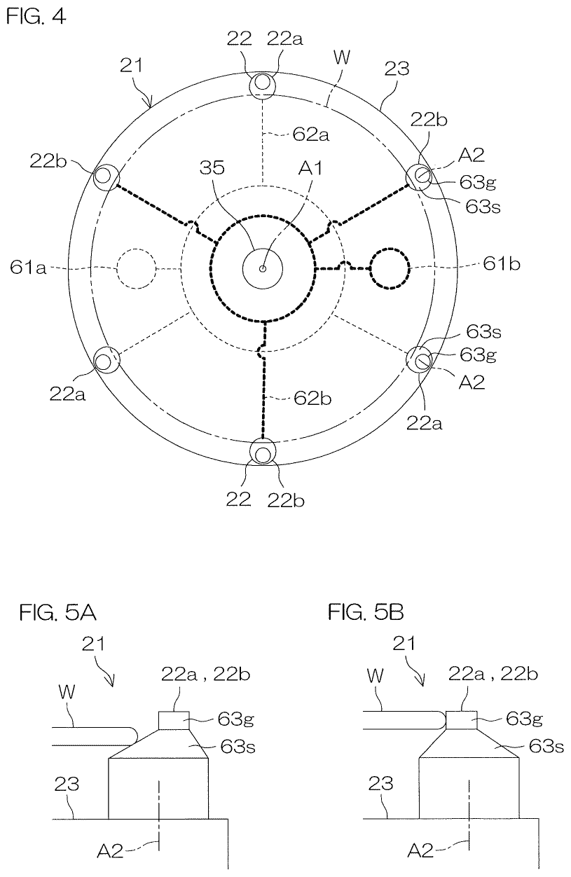

FIG. 4 is a plan view of the spin chuck 21. FIG. 5A is a schematic view of the chuck pin 22 positioned at an open position as viewed horizontally. FIG. 5B is a schematic view of the chuck pin 22 positioned at a closed position as viewed horizontally.

As shown in FIG. 4, the plurality of chuck pins 22 include a plurality of first chuck pins 22a horizontally clamping the substrate W and a plurality of second chuck pins 22b horizontally clamping the substrate W. FIG. 4 shows an example in which three first chuck pins 22a and three second chuck pins 22b are alternately arranged at equal intervals in the circumferential direction of the substrate W. The number of first chuck pins 22a and the number of second chuck pins 22b are not limited to the example shown in FIG. 4. The same applies to the arrangement of the first chuck pin 22a and the second chuck pin 22b. The number of the first chuck pins 22a may be equal to or different from the number of the second chuck pins 22b. Specifications of the first chuck pin 22a such as a shape, size, weight, and material may be equal to or different from those of the second chuck pin 22b.

As shown in FIGS. 5A and 5B, both the first chuck pin 22a and the second chuck pin 22b are movable with respect to the spin base 23 between the open position away from the end surface of the substrate W and the closed position in contact with the end surface of the substrate W. As shown in FIG. 4, the spin chuck 21 includes a first actuator 61a that moves each of the plurality of first chuck pins 22a between the open position and the closed position, and a second actuator 61b that moves each of the plurality of second chuck pins 22b between the open position and the closed position. In FIG. 4, the second actuator 61b and a second power transmission path 62b are indicated by thick broken lines. The first actuator 61a may be an electric motor or an air cylinder, or may be other than these. The same applies to the second actuator 61b.

The spin chuck 21 further includes a first power transmission path 62a that transmits the power of the first actuator 61a to each of the plurality of first chuck pins 22a, and a second power transmission path 62b that transmits the power of the second actuator 61b to each of the plurality of second chuck pins 22b. The first actuator 61a and the first power transmission path 62a are disposed in an internal space of the spin chuck 21 formed by the spin base 23 and a chuck housing 26 (see FIG. 2A). The same applies to the second actuator 61b and the second power transmission path 62b.

The first power transmission path 62a transmits the power of the first actuator 61a to all the first chuck pins 22a while converting the motion of the first actuator 61a into the motion of the first chuck pins 22a. When any one of the first chuck pins 22a is disposed at the open position, all the other first chuck pins 22a are also disposed at the open position. The same applies to the second power transmission path 62b and the second chuck pins 22b.

The first power transmission path 62a may be a physically continuous or non-continuous path from the first actuator 61a to all the first chuck pins 22a. In any case, the first power transmission path 62a may include mechanical elements such as a cam, link, and ball screw. When the first power transmission path 62a is not physically continuous from the first actuator 61a to all the first chuck pins 22a, the first power transmission path 62a may transmit the power of the first actuator 61a to all the first chuck pins 22a via the magnetic force of an electromagnet or permanent magnet. The same applies to the second power transmission path 62b.

The first actuator 61a may move the first chuck pins 22a to the open position side and the closed position side, or may move the first chuck pins 22a only to the open position side. The same applies to the second actuator 61b. In the latter case, the first chuck pins 22a movable between the initial position and the open position may be positioned at the initial position by the force of a magnet or spring. In this case, when the force with which the first actuator 61a positions the first chuck pins 22a at the open position is lost, the first actuator 61a returns to the initial position via the closed position by the force of the magnet or spring. At this time, when the substrate W is inside the plurality of first chuck pins 22a, the first chuck pins 22a come into contact with the end surface of the substrate W and stop at the closed position. The substrate W is thereby gripped by the plurality of first chuck pins 22a.

FIGS. 5A and 5B show an example in which each of the first chuck pin 22a and the second chuck pin 22b includes a supporting portion 63s disposed below the substrate W and a gripping portion 63g disposed outside the substrate W. The substrate W is placed in a horizontal posture on the supporting portions 63s of the first chuck pins 22a and the second chuck pins 22b in a state where all the gripping portions 63g are separated from the end surface of the substrate W. The gripping portions 63g of the plurality of first chuck pins 22a are horizontally pressed against the end surface of the substrate W supported by the supporting portions 63s of the first chuck pins 22a and the second chuck pins 22b. The same applies to the gripping portions 63g of the plurality of second chuck pins 22b.

FIGS. 5A and 5B show an example in which a truncated cone-shaped tapered surface that narrows upward is the supporting portion 63s, and a vertical cylindrical surface extending upward from an upper edge of the tapered surface is the gripping portion 63g. In this example, the supporting portion 63s and the gripping portion 63g rotate with respect to the spin base 23 around a vertical rotational axis A2 different from a vertical center line of the gripping portion 63g. When the first chuck pins 22a or the second chuck pins 22b are rotated with respect to the spin base 23, the distance in the horizontal direction from the vertical rotational axis A1 (see FIG. 4) of the substrate W to the gripping portion 63g increases or decreases.

The shapes of the first chuck pins 22a and the second chuck pins 22b are not limited to the shapes shown in FIGS. 5A and 5B. Each of the first chuck pins 22a and the second chuck pins 22b may include a base plate rotatable with respect to the spin base 23 about the vertical rotational axis A2, a supporting portion 63s extending upward from the base plate, and a gripping portion 63g extending upward from the base plate at a position away from the supporting portion 63s. The gripping portion 63g may be two planes forming a V-shaped groove opened to the substrate W side. The supporting portion 63s may be a plane inclined with respect to the horizontal plane, or may be a hemispherical surface in point contact with the lower surface of the substrate W. The supporting portion 63s may be a portion or all of support pins held by the spin base 23 at a position away from the first chuck pins 22a and the second chuck pins 22b.

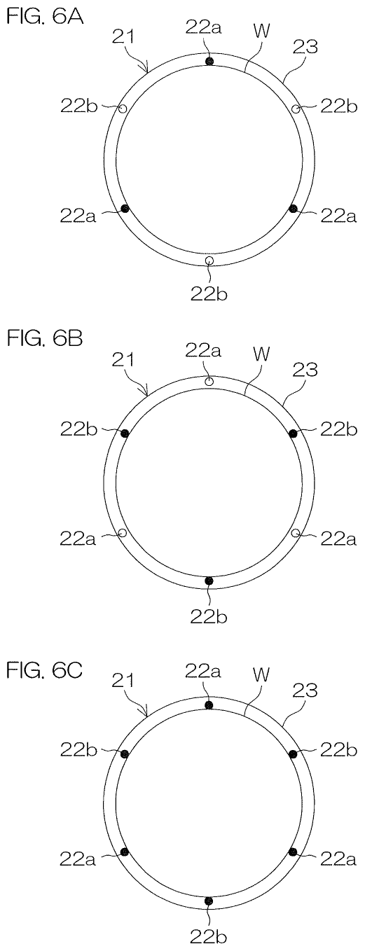

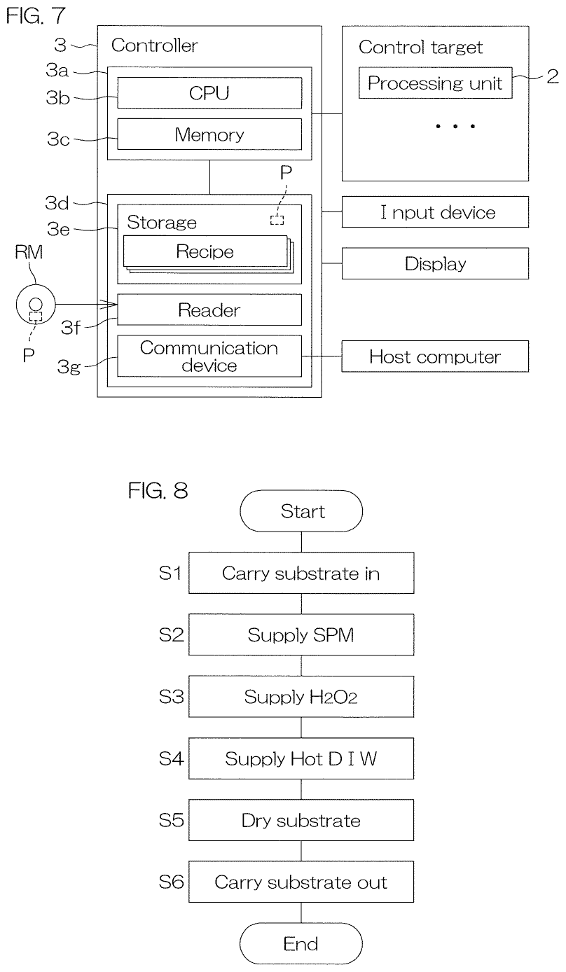

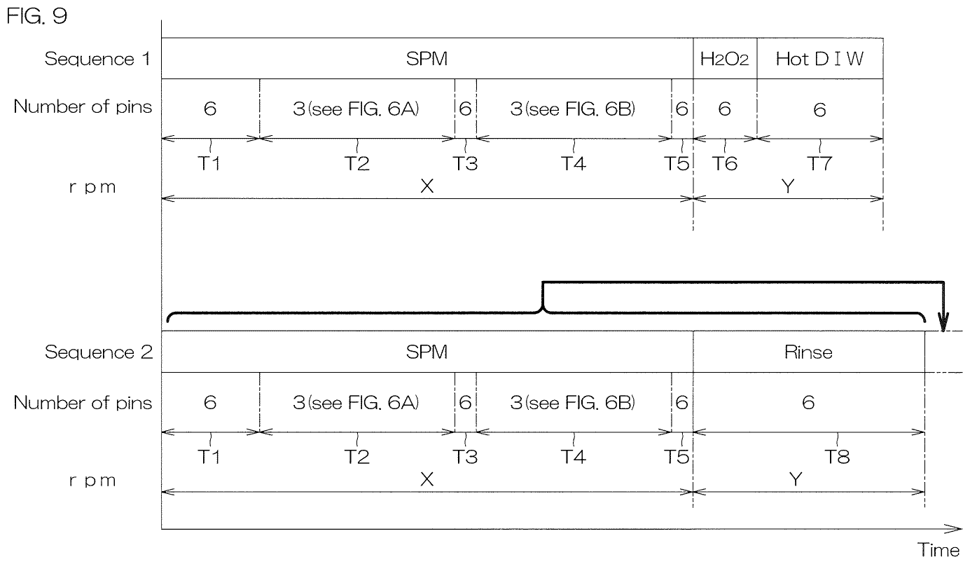

FIG. 6A is a schematic plan view showing the plurality of chuck pins 22 in the first closed state. FIG. 6B is a schematic plan view showing the plurality of chuck pins 22 in the second closed state. FIG. 6C is a schematic plan view showing the plurality of chuck pins 22 in the fully closed state. In FIGS. 6A to 6C, the first chuck pins 22a and the second chuck pins 22b located at the closed position are filled in black.

In the first closed state shown in FIG. 6A, the gripping portion 63g of the first chuck pin 22a comes into contact with the end surface of the substrate W, and the gripping portion 63g of the second chuck pin 22b is separated from the end surface of the substrate W. In the second closed state shown in FIG. 6B, the gripping portion 63g of the first chuck pin 22a is separated from the end surface of the substrate W, and the gripping portion 63g of the second chuck pin 22b comes into contact with the end surface of the substrate W. In the fully closed state shown in FIG. 6C, the gripping portion 63g of the first chuck pin 22a comes into contact with the end surface of the substrate W, and the gripping portion 63g of the second chuck pin 22b comes into contact with the end surface of the substrate W. In the fully open state shown in FIG. 4, the gripping portion 63g of the first chuck pin 22a is separated from the end surface of the substrate W, and the gripping portion 63g of the second chuck pin 22b is separated from the end surface of the substrate W.

Next, an electrical arrangement of the substrate processing apparatus 1 will be described.

FIG. 7 is a block diagram showing the electrical arrangement of the substrate processing apparatus 1. The controller 3 is a computer that includes a computer main body 3a and a peripheral device 3d that is connected to the computer main body 3a. The computer main body 3a includes a CPU 3b (central processing unit) that executes various types of commands and a memory 3c that stores information. The peripheral device 3d includes a storage 3e that stores information to be sent to and received from the memory 3c such as a program P, a reader 3f that reads information from a removable medium RM, and a communication device 3g that communicates with other devices such as a host computer.

The controller 3 is connected to an input device and a display. The input device is operated when an operator such as a user or a maintenance operator inputs information to the substrate processing apparatus 1. The information is displayed on the screen of the display. The input device may be any one of a keyboard, a pointing device and a touch panel or may be a device other than those. A touch panel display that serves both as the input device and the display may be provided in the substrate processing apparatus 1.

The CPU 3b executes the program P stored in the storage 3e. The program P within the storage 3e may be previously installed in the controller 3, may be fed through the reader 3f from the removable medium RM to the storage 3e or may be fed from an external device such as the host computer to the storage 3e through the communication device 3g.

The memory 3c is a volatile memory that retains memory only when power is supplied. The storage 3e and the removable medium RM are non-volatile memories that retain memory even when power is not supplied. The storage 3e is, for example, a magnetic storage device such as a hard disk drive. The removable medium RM is, for example, an optical disc such as a compact disc or a semiconductor memory such as a memory card. The removable medium RM is an example of a computer readable recording medium in which the program P is recorded. The removable medium RM is a non-transitory tangible recording medium (non-transitory tangible media).

The storage 3e stores a plurality of recipes. The recipe is information that specifies the details of processing, processing conditions and processing procedures of the substrate W. A plurality of recipes differ from each other in at least one of the details of processing, the processing conditions and the processing procedures of the substrate W. The controller 3 controls the substrate processing apparatus 1 such that the substrate 3 is processed according to the recipe designated by the host computer. The controller 3 is programmed to execute the individual steps described below. The controller 3 is programmed to execute the individual steps described below.

Next, an example of processing of the substrate W will be described.

FIG. 8 is a process chart for describing one example of processing for the substrate W by the substrate processing apparatus 1. In the following, FIG. 2A, FIG. 2B, and FIG. 8 shall be referred to. HotDIW in FIG. 8 represents hot water (pure water having a temperature higher than room temperature). The same applies to other drawings.

The substrate W includes a front surface and a rear surface parallel to each other, and an annular end surface that connects outer edges of the front surface and the rear surface over the entire circumference of the front surface and the rear surface. The front surface and the rear surface of the substrate W are flat surfaces parallel to each other. The front surface of the substrate W is a device-forming surface on which a device is formed. The rear surface of the substrate W is a non-device-forming surface on which no device is formed. Both the front surface and the rear surface of the substrate W may be the device-forming surfaces.

Hereinafter, an example in which a thin film is removed from a front surface and an end surface of a disk-shaped semiconductor wafer such as a silicon wafer will be described. The thin film to be removed may be a resist film or a thin film other than the resist film such as a metal film. The metal film may be any one of a Ti film, TiN film, and NiPt film, or may be other than these.

In the case of removing the metal film from the front surface and the end surface of the semiconductor wafer, which is one example of the substrate W, a step of forming a transistor on the front surface of the semiconductor wafer, a step of forming a metal film on the front surface of the semiconductor wafer on which the transistor is formed, and a step of forming a silicide by heating the semiconductor wafer on which the metal film is formed may be performed before the steps described below.

When the substrate W is to be processed by the substrate processing apparatus 1, a carry-in step of carrying the substrate W into the chamber 12 is performed (step S1 of FIG. 8).

Specifically, in a state where all of the guards 44 are positioned at the lower positions and all of the scan nozzles are positioned at the standby positions, the center robot CR (see FIG. 1A) makes the hand Hc enter inside the chamber 12 while supporting the substrate W horizontally with the hand Hc. Thereafter, the center robot CR places the substrate W, on the hand Hc, on the plurality of chuck pins 22 in a state where the front surface of the substrate W is faced upward. Thereafter, the center robot CR makes the hand Hc retreat from inside the chamber 12.

After the substrate W is placed on the plurality of chuck pins 22, the plurality of chuck pins 22 are pressed against an outer circumferential surface of the substrate W and the substrate W is gripped. Thereafter, the electric motor 25 is driven, and the rotation of the substrate W is started. Accordingly, the substrate W rotates at a chemical liquid supplying speed. Before or after the rotation of the substrate W is started, the guard raising/lowering unit 47 raises at least one of the guards 44 from the lower position to the upper position.

Next, a chemical liquid supply step (step S2 in FIG. 8) of supplying SPM, which is an example of the chemical liquid, to the upper surface of the substrate W to form a liquid film of the SPM covering the entire upper surface of the substrate W is performed.

Specifically, in a state where at least one of the guards 44 is positioned at the upper position, the first nozzle moving unit 30 moves the chemical liquid nozzle 27 from the standby position to the processing position. Thereafter, the sulfuric acid valve 28v and the hydrogen peroxide water valve 29v are opened and the chemical liquid nozzle 27 starts discharge of the SPM. The SPM that is discharged from the chemical liquid nozzle 27 collides with the upper surface of the substrate W that is rotating at the chemical liquid supplying speed and thereafter flows outward along the upper surface of the substrate W by a centrifugal force. Therefore, the SPM is supplied to the entire upper surface of the substrate W and a liquid film of the SPM that covers the entire upper surface of the substrate W is formed. While the chemical liquid nozzle 27 is discharging the SPM, the first nozzle moving unit 30 may move a collision position of the SPM with respect to the upper surface of the substrate W such that the collision position passes the central portion and the outer circumferential portion or may keep the collision position still at the central portion. Whether or not to move the collision position is the same for the processing liquid supplied to the upper surface of the substrate W after the SPM.

Next, a replacement liquid supply step (step S3 in FIG. 8) of supplying the hydrogen peroxide water, which is an example of the replacement liquid, to the upper surface of the substrate W to replace the SPM on the substrate W with the hydrogen peroxide water is performed.

Specifically, the sulfuric acid valve 28v is closed in a state where the at least one guard 44 is located at the upper position and the chemical liquid nozzle 27 located at the processing position is discharging the SPM. Accordingly, the discharge of the SPM from the chemical liquid nozzle 27 is stopped, and the chemical liquid nozzle 27 starts the discharge of the hydrogen peroxide water. Before or after the discharge of the hydrogen peroxide water is started, the guard raising/lowering unit 47 may move the at least one of the guards 44 vertically to switch the guard 44 that receives the liquid discharged from the substrate W.

The hydrogen peroxide water that is discharged from the chemical liquid nozzle 27 collides with the upper surface of the substrate W that is rotating at a replacement liquid supplying speed and thereafter flows outward along the upper surface of the substrate W by a centrifugal force. The SPM on the substrate W is replaced with the hydrogen peroxide water discharged from the chemical liquid nozzle 27. A liquid film of the hydrogen peroxide water that covers the entire upper surface of the substrate W is thereby formed. When a predetermined time elapses after the sulfuric acid valve 28v is closed, the hydrogen peroxide water valve 29v is closed and the discharge of the hydrogen peroxide water is stopped. Thereafter, the first nozzle moving unit 30 moves the chemical liquid nozzle 27 to the standby position.

Next, a rinse liquid supply step (step S4 in FIG. 8) of supplying hot water, which is an example of the rinse liquid, to the upper surface of the substrate W to wash away the hydrogen peroxide water on the substrate W is performed.

Specifically, in a state where at least one of the guards 44 is positioned at the upper position, the second nozzle moving unit 34 moves the rinse liquid nozzle 31 from the standby position to the processing position. Thereafter, the hot water valve 33v is opened and the rinse liquid nozzle 31 starts discharge of hot water. Before the discharge of hot water is started, the guard raising/lowering unit 47 may move the at least one of the guards 44 vertically to switch the guard 44 that receives the liquid discharged from the substrate W.

The hot water that is discharged from the rinse liquid nozzle 31 collides with the upper surface of the substrate W that is rotating at a rinse liquid supplying speed and thereafter flows outward along the upper surface of the substrate W by a centrifugal force. The hydrogen peroxide water on the substrate W is replaced with the hot water discharged from the rinse liquid nozzle 31. A liquid film of the hot water that covers the entire upper surface of the substrate W is thereby formed. When a predetermined time elapses from when the hot water valve 33v was opened, the hot water valve 33v is closed and the discharge of hot water is stopped. Thereafter, the second nozzle moving unit 34 moves the rinse liquid nozzle 31 to the standby position.

Next, a drying step (step S5 in FIG. 8) of removing hot water from the upper surface of the substrate W and drying the substrate W is performed.

Specifically, the electric motor 25 accelerates the substrate W in the rotation direction, and rotates the substrate W at a high rotational speed (for example, several thousand rpm) larger than the rotational speed of the substrate W from the chemical liquid supply step to the rinse liquid supply step. When the electric motor 25 starts high speed rotation of the substrate W, hot water scatters outward from the substrate W and is removed from the upper surface of the substrate W. As a result, the substrate W is dried. When a predetermined time elapses from when the high speed rotation of the substrate W was started, the electric motor 25 stops the rotation. As a result, the rotation of the substrate W is stopped.

Next, a carry-out step (step S6 in FIG. 8) of carrying out the substrate W from the chamber 12 is performed.

Specifically, the guard raising/lowering unit 47 lowers all the guards 44 to the lower position. Thereafter, the center robot CR causes the hand Hc to enter the chamber 12. After the plurality of chuck pins 22 release the gripping of the substrate W, the center robot CR supports the substrate W on the spin chuck 21 with the hand Hc. Thereafter, the center robot CR makes the hand Hc retreat from inside the chamber 12 while supporting the substrate W with the hand Hc horizontally. The processed substrate W is thereby carried out from the chamber 12.

Next, the number of chuck pins 22 to be brought into contact with the end surface of the substrate W will be described.

FIG. 9 is a diagram for describing the number of chuck pins 22 in contact with the end surface of the substrate W when the processing liquid such as SPM is supplied to the substrate W. The “number of pins” in FIG. 9 represents the number of chuck pins 22 in contact with the end surface of the substrate W, and the “rpm” in FIG. 9 represents the rotational speed of the substrate W.

FIG. 9 shows a sequence 1 that is an example of supplying the SPM, the hydrogen peroxide water, and the hot water to the substrate W in this order, and a sequence 2 that is an example of supplying the SPM and the rinse liquid to the substrate W in this order. A specific processing flow in the sequence 1 is similar to the processing flow shown in FIG. 8. When the SPM is supplied to the substrate W in the sequence 1 and the sequence 2, the substrate W is rotated in a state where all the first chuck pins 22a and all the second chuck pins 22b are in contact with the end surface of the substrate W (a state shown in FIG. 6C). In this state, the supply of the SPM to the substrate W is started. A liquid film of the SPM that covers the entire upper surface of the substrate W is thereby formed.

When a first chemical liquid supplying time T1 elapses after the supply of the SPM is started, all the second chuck pins 22b are separated from the end surface of the substrate W while all the first chuck pins 22a are in contact with the end surface of the substrate W (see FIG. 6A). When a second chemical liquid supplying time T2 elapses, all the second chuck pins 22b are brought into contact with the end surface of the substrate W (see FIG. 6C). Thereafter, when a third chemical liquid supplying time T3 elapses, all the first chuck pins 22a are separated from the end surface of the substrate W while all the second chuck pins 22b are in contact with the end surface of the substrate W (see FIG. 6B). Thereafter, when a fourth chemical liquid supplying time T4 elapses, all the first chuck pins 22a are brought into contact with the end surface of the substrate W (see FIG. 6C).

When a fifth chemical liquid supplying time T5 elapses after all the first chuck pins 22a are brought into contact with the end surface of the substrate W in the sequence 1, the supply of the SPM to the substrate W is stopped in a state where all the first chuck pins 22a and all the second chuck pins 22b are brought into contact with the end surface of the substrate W, and the supply of hydrogen peroxide water to the substrate W is started. Accordingly, the high-temperature SPM on the substrate W is replaced with the hydrogen peroxide water at room temperature, and a liquid film of the hydrogen peroxide water covering the entire upper surface of the substrate W is formed. Thereafter, in a state where all the first chuck pins 22a and all the second chuck pins 22b are brought into contact with the end surface of the substrate W, the supply of hydrogen peroxide water to the substrate W is stopped, and the supply of hot water to the substrate W is started. Thereby, the hydrogen peroxide water on the substrate W is replaced with the hot water, and a liquid film of the hot water covering the entire upper surface of the substrate W is formed.

When a fifth chemical liquid supplying time T5 elapses after all the first chuck pins 22a are brought into contact with the end surface of the substrate W in the sequence 2, the supply of the SPM to the substrate W is stopped in a state where all the first chuck pins 22a and all the second chuck pins 22b are brought into contact with the end surface of the substrate W, and the supply of rinse liquid to the substrate W is started. £ Accordingly, the high-temperature SPM on the substrate W is replaced with the rinse liquid at room temperature, and a liquid film of the rinse liquid covering the entire upper surface of the substrate W is formed. The rinse liquid may be pure water at room temperature or a liquid other than the pure water.

In the sequence 1 and the sequence 2, while the SPM is supplied to the substrate W, the chuck pins 22 in contact with the end surface of the substrate Ware switched in this order: the six first chuck pins 22a and second chuck pins 22b, the three first chuck pins 22a, the six first chuck pins 22a and second chuck pins 22b, the three second chuck pins 22b, the six first chuck pins 22a and second chuck pins 22b. While the hydrogen peroxide water or the rinse liquid is supplied to the substrate W, the chuck pins 22 in contact with the end surface of the substrate W are maintained by the six first chuck pins 22a and second chuck pins 22b.

The first chemical liquid supplying time T1 is shorter than the second chemical liquid supplying time T2. The first chemical liquid supplying time T1 is shorter than the fourth chemical liquid supplying time T4. The second chemical liquid supplying time T2 may be equal to or different from the fourth chemical liquid supplying time T4. The first chemical liquid supplying time T1 is longer than the third chemical liquid supplying time T3. The first chemical liquid supplying time T1 is longer than the fifth chemical liquid supplying time T5. The third chemical liquid supplying time T3 may be equal to or different from the fifth chemical liquid supplying time T5. The first chemical liquid supplying time T1 may be equal to or different from a period during which the hydrogen peroxide water is supplied to the substrate W (hereinafter, a replacement liquid supplying time T6). The first chemical liquid supplying time T1 may be equal to or different from a period during which the hot water is supplied to the substrate W (hereinafter, a rinse liquid supplying time T7). The first chemical liquid supplying time T1 may be equal to or different from a period during which the rinse liquid is supplied to the substrate W (hereinafter, a rinse liquid Supplying time T8).

The replacement liquid supplying time T6 is longer than each of the third chemical liquid supplying time T3 and the fifth chemical liquid supplying time T5 and shorter than the first chemical liquid supplying time T1. The rinse liquid supplying time T7 is longer than the first chemical liquid supplying time T1 and shorter than each of the second chemical liquid supplying time T2 and the fourth chemical liquid supplying time T4. The rinse liquid supplying time T8 is longer than each of the second chemical liquid supplying time T2 and the fourth chemical liquid supplying time T4, and is shorter than the period during which the SPM is supplied to the substrate W (the sum of the first chemical liquid supplying time T1 to the fifth chemical liquid supplying time T5). The lengths of the replacement liquid supplying time T6, the rinse liquid supplying time T7, and the rinse liquid supplying time T8 are not limited to the example shown in FIG. 9. Similarly, the length of the first chemical liquid supplying time T1 to the fifth chemical liquid supplying time T5 is not limited to the example shown in FIG. 9.

All the first chuck pins 22a or all the second chuck pins 22b may be separated from the end surface of the substrate W after at least the first chemical liquid supplying time T1 has elapsed from the start of the supply of the hydrogen peroxide water or the rinse liquid to the substrate W in the sequence 1 and the sequence 2. Alternatively, all the first chuck pins 22a or all the second chuck pins 22b may be separated from the end surface of the substrate W before the first chemical liquid supplying time T1 has elapsed from the start of the supply of the hydrogen peroxide water or the rinse liquid to the substrate W in the sequence 1 and the sequence 2.

The rotational speed of the substrate W when the SPM is supplied to the substrate W may be constant or may change. The same applies when the hydrogen peroxide water, the hot water, and the rinse liquid are supplied to the substrate W. The rotational speed (chemical liquid supplying speed) of the substrate W when the SPM is supplied to the substrate W may be equal to or different from the rotational speed (replacement liquid supplying speed) of the substrate W when the hydrogen peroxide water is supplied to the substrate W. Similarly, the chemical liquid supplying speed may be equal to or different from the rotational speed (rinse liquid supplying speed) of the substrate W when the hot water or the rinse liquid is supplied to the substrate W. When the rotational speed changes, the maximum value of the rotational speed may be used as a comparison target.

In the sequence 1 and the sequence 2, the rotational speed of the substrate W is maintained at a first rotational speed X, then increased from the first rotational speed X to a second rotational speed Y, and maintained at the second rotational speed Y. The increase in the rotational speed 41 the substrate 3 from the first rotational speed X to the second rotational speed Y is started in a state where all the first chuck pins 22a and all the second chuck pins 22b are in contact with the end surface of the substrate W. The increase in the rotational speed of the substrate W may be started at the same time as the fifth chemical liquid supplying time T5 elapses, or may be started before or after the fifth chemical liquid supplying time T5 elapses. In either case, the rotational speed of the substrate W is maintained at the first rotational speed X until the fourth chemical liquid supplying time T4 elapses. Therefore, the number of chuck pins 22 in contact with the end surface of the substrate W is changed in a state where the substrate W is rotating at a constant rotational speed.

As indicated by a thick line in the sequence 2, the SPM and the rinse liquid may be supplied to the substrate W and then the SPM and the rinse liquid may be supplied to the substrate W again. The number of chuck pins 22 to be brought into contact with the end surface of the substrate W, the rotational speed of the substrate W in the second supply of the SPM and the rinse liquid are the same as those in the first supply of the SPM and the rinse liquid. Also in the sequence 1, the second supply of the SPM, the hydrogen peroxide water, and the hot water may be performed.

When the first chuck pin 22a are separated from the end surface of the substrate W while the SPM is supplied to the substrate W, the SPM enters between the substrate W and the first chuck pins 22a, and is supplied to a portion in contact with the first chuck pins 22a on the end surface of the substrate W. Similarly, when the second chuck pins 22b are separated from the end surface of the substrate W while the SPM is supplied to the substrate W, the SPM enters between the substrate W and the second chuck pins 22b, and is supplied to a portion in contact with the second chuck pins 22b on the end surface of the substrate W. Therefore, when the first chuck pins 22a and the second chuck pins 22b are separated from the end surface of the substrate W once or more while the SPM is supplied to the substrate W, the SPM can be supplied to the entire end surface of the substrate W.

In the sequence 1 and the sequence 2, the entire period during which the plurality of first chuck pins 22a and the plurality of second chuck pins 22b are brought into contact with the end surface of the substrate W at the start of supply of the SPM corresponds to the first division step, and the entire period during which the plurality of first chuck pins 22a are brought into contact with the end surface of the substrate W and the plurality of second chuck pins 22b are separated from the end surface of the substrate W corresponds to the second division step. Similarly, the entire period during which the plurality of first chuck pins 22a and the plurality of second chuck pins 22b are brought into contact with the end surface of the substrate W during the supply of the SPM corresponds to the third division step, the entire period during which the plurality of first chuck pins 22a are separated from the end surface of the substrate W and the plurality of second chuck pins 22b are brought into contact with the end surface of the substrate W corresponds to the fourth division step, and the entire period during which the first chuck pins 22a and the plurality of second chuck pins 22b are brought into contact with the end surface of the substrate W at the end of the supply of the SPM corresponds to the fifth division step. In the sequence 1, the entire period during which the hydrogen peroxide water is supplied to the substrate W corresponds to the replacement liquid supply step. In the sequence 2, the entire period during which the rinse liquid is supplied to the substrate W corresponds to the replacement liquid supply step. The first to fifth division steps are a series of continuous steps in which the chemical liquid supply step (step S2 in FIG. 8) is divided into five according to the states of the plurality of first chuck pins 22a and the plurality of second chuck pins 22b.

Next, the advantages according to the embodiment will be described.

In the present embodiment, in a state where at least one of the plurality of first chuck pins 22a and the plurality of second chuck pins 22b are in contact with the end surface of the horizontal substrate W, a sulfuric acid-containing liquid such as SPM is supplied to the substrate W while rotating the substrate W. Specifically, the supply of the sulfuric acid-containing liquid to the substrate W is started in the fully closed state where the plurality of first chuck pins 22a and the plurality of second chuck pins 22b are in contact with the end surface of the substrate W. Thereafter, the plurality of first chuck pins 22a and the plurality of second chuck pins 22b are switched to the first closed state where the plurality of first chuck pins 22a are in contact with the end surface of the substrate W and the plurality of second chuck pins 22b are separated from the end surface of the substrate W. Thereafter, the plurality of first chuck pins 22a and the plurality of second chuck pins 22b are switched to the fully closed state. Thereafter, the plurality of first chuck pins 22a and the plurality of second chuck pins 22b are switched to the second closed state where the plurality of second chuck pins 22b are in contact with the end surface of the substrate W.

The sulfuric acid-containing liquid is a liquid having a temperature higher than the temperature of the substrate W before the sulfuric acid-containing liquid is supplied. When the supply of the sulfuric acid-containing liquid to the substrate W is started, the temperature of the substrate W rises, and the temperature of the substrate W is unevenly distributed. When a certain period of time elapses after the supply of the sulfuric acid-containing liquid is started, the temperature of the substrate W is stabilized, and such uneven temperature distribution is eliminated or reduced. When the temperature of the substrate W varies, the substrate W is deformed. When the supply of the sulfuric acid-containing liquid to the substrate W is started, both the plurality of first chuck pins 22a and the plurality of second chuck pins 22b are in contact with the end surface of the substrate W. Therefore, it is possible to supply the sulfuric acid-containing liquid to the substrate W while more reliably stabilizing the posture of the substrate W as compared with a case where the supply of the sulfuric acid-containing liquid is started in a state where only the plurality of first chuck pins 22a or only the plurality of second chuck pins 22b are in contact with the end surface of the substrate W.

After the supply of the sulfuric acid-containing liquid to the substrate W is started, only the plurality of first chuck pins 22a are brought into contact with the end surface of the substrate W, and then only the plurality of second chuck pins 22b are brought into contact with the end surface of the substrate W. When the first chuck pins 22a are separated from the end surface of the substrate W, the sulfuric acid-containing liquid enters between the substrate W and the first chuck pins 22a, and is supplied to a portion included in the end surface of the substrate W and being in contact with the first chuck pins 22a. When the second chuck pins 22b are separated from the end surface of the substrate W, the sulfuric acid-containing liquid is also supplied to a portion included in the end surface of the substrate W and being in contact with the second chuck pins 22b. As a result, the sulfuric acid-containing liquid can be supplied to the entire end surface of the substrate W, and the end surface of the substrate W can be uniformly processed with the sulfuric acid-containing liquid.

In the present embodiment, the plurality of first chuck pins 22a and the plurality of second chuck pins 22b are switched from a state where only the plurality of second chuck pins 22b are in contact with the end surface of the substrate W to a state where both the plurality of first chuck pins 22a and the plurality of second chuck pins 22b are in contact with the end surface of the substrate W. In this state, the sulfuric acid-containing liquid in contact with the substrate W is replaced with a replacement liquid such as the hydrogen peroxide water or rinse liquid. The replacement liquid is a liquid having a lower temperature than that of the sulfuric acid-containing liquid. When the supply of the replacement liquid to the substrate W is started, the temperature of the substrate W decreases, and the substrate W is deformed. When the supply of the replacement liquid to the substrate W is started, both the plurality of first chuck pins 22a and the plurality of second chuck pins 22b are brought into contact with the end surface of the substrate W. Therefore, it is possible to supply the replacement liquid to the substrate W while more reliably stabilizing the posture of the substrate W as compared with a case where the supply of the replacement liquid is started in a state where only the plurality of first chuck pins 22a or only the plurality of second chuck pins 22b are in contact with the end surface of the substrate W.

In the present embodiment, the replacement liquid is started to be supplied to the substrate W in a state where the substrate W is rotated at a higher speed than when the sulfuric acid-containing liquid is supplied to the substrate W. As the rotational speed of the substrate W increases, the force applied to the substrate W also increases. Further, when the supply of the replacement liquid to the substrate W is started, the temperature of the substrate W decreases, and the substrate W is deformed. When the supply of the replacement liquid to the substrate W is started, both the plurality of first chuck pins 22a and the plurality of second chuck pins 22b are brought into contact with the end surface of the substrate W. Therefore, it is possible to supply the replacement liquid to the substrate W while more reliably stabilizing the posture of the substrate W as compared with a case where the supply of the replacement liquid is started in a state where only the plurality of first chuck pins 22a or only the plurality of second chuck pins 22b are in contact with the end surface of the substrate W.

In the present embodiment, the sulfuric acid-containing liquid in contact with the substrate W is replaced with hydrogen peroxide water corresponding to the replacement liquid. The hydrogen peroxide water is a liquid having a lower temperature than that of the sulfuric acid-containing liquid. When hydrogen peroxide contained in the hydrogen peroxide water reacts with sulfuric acid contained in the sulfuric acid-containing liquid, heat is generated. Therefore, the temperature decrease of the substrate W can be alleviated by the heat of reaction between sulfuric acid and hydrogen peroxide, and the rate at which the substrate W deforms can be reduced. Accordingly, it is possible to supply the hydrogen peroxide water corresponding to the replacement liquid to the substrate W while more reliably stabilizing the posture of the substrate W.

In the present embodiment, the sulfuric acid-containing liquid having a temperature higher than that of the substrate W is supplied to the substrate W, and then the replacement liquid having a temperature lower than that of the sulfuric acid-containing liquid is supplied to the substrate W. Thereafter, the sulfuric acid-containing liquid is supplied to the substrate W again. When the high-temperature sulfuric acid-containing liquid is continuously supplied to the substrate W for a long time, members in contact with the substrate W, such as the first chuck pins 22a and the second chuck pins 22b, have a high temperature. When the sulfuric acid-containing liquid is replaced with the low-temperature replacement liquid and then the sulfuric acid-containing liquid is supplied again, the period during which the temperature of the members in contact with the substrate W is high can be shortened.

In the present embodiment, the plurality of first chuck pins 22a and the plurality of second chuck pins 22b are switched between two of the fully closed state, the first closed state, and the second closed state while the rotational speed of the substrate W is maintained constant. When the substrate W is accelerated in the rotation direction, the force applied to the substrate W increases. When the rotational speed of the substrate W is constant, the fluctuation of the force applied to the substrate W with the rotation of the substrate W is small. In such a state, the states of the plurality of first chuck pins 22a and the plurality of second chuck pins 22b are switched. Accordingly, it is possible to supply the sulfuric acid-containing liquid to the substrate W while more reliably stabilizing the posture of the substrate W.

In the present embodiment, the plurality of first chuck pins 22a or the plurality of second chuck pins 22b are separated from the end surface of the substrate W while maintaining the constant rotational speed of the substrate W. When the plurality of first chuck pins 22a or the plurality of second chuck pins 22b are separated from the end surface of the substrate W, the force to hold the substrate W is weakened. If the rotational speed of the substrate W is kept constant at such a time, the states of the plurality of first chuck pins 22a and the plurality of second chuck pins 22b can be switched while more reliably stabilizing the posture of the substrate W.

In the present embodiment, the sulfuric acid-containing liquid is supplied to the substrate W that is not in contact with the liquid and is in contact with a tangible object such as the first chuck pins 22a and air. When the sulfuric acid-containing liquid is supplied to the substrate W to which the liquid is attached, the heat of the sulfuric acid-containing liquid is also transmitted to the liquid attached to the substrate W, so that the temperature rise of the substrate W is alleviated. When the sulfuric acid-containing liquid is supplied to the substrate W to which no liquid is attached, the temperature rise of the substrate W increases as compared with the above case. Therefore, when the sulfuric acid-containing liquid is supplied to the substrate W not in contact with the liquid, by bringing both the plurality of first chuck pins 22a and the plurality of second chuck pins 22b into contact with the end surface of the substrate W, it is possible to supply the sulfuric acid-containing liquid to the substrate 3 while more reliably stabilizing the posture of the substrate W.

In the present embodiment, the period during which both the plurality of first chuck pins 22a and the plurality of second chuck pins 22b are in contact with the end surface of the substrate W at the start of supply of the sulfuric acid-containing liquid is made shorter than the period during which only the plurality of first chuck pins 22a or only the plurality of second chuck pins 22b are in contact with the end surface of the substrate W. In other words, the period during which the plurality of first chuck pins 22a or the plurality of second chuck pins 22b are separated from the end surface of the substrate W is lengthened. Accordingly, it is possible to lengthen the period during which the sulfuric acid-containing liquid is supplied to the portion in contact with the first chuck pins 22a or the second chuck pins 22b on the end surface of the substrate W.

In the present embodiment, the period of the fully closed state at the start of the supply of the sulfuric acid-containing liquid is made longer than the period of the fully closed state during the supply of the sulfuric acid-containing liquid. Since the period of the fully closed state at the start of supply of the sulfuric acid-containing liquid is long, the plurality of first chuck pins 22a and the plurality of second chuck pins 22b can be switched from the fully closed state to the first closed state in a state where the rate of change in the temperature of the substrate W is small. Furthermore, since the period of the fully closed state during the supply of the sulfuric acid-containing liquid is short, that is, the period until the plurality of first chuck pins 22a and the plurality of second chuck pins 22b are switched from the first closed state to the second closed state is short, the period during which the sulfuric acid-containing liquid is supplied to the portion in contact with the first chuck pins 22a or the second chuck pins 22b on the end surface of the substrate W can be lengthened.

Next, other embodiments will be described.

A sulfuric acid-containing liquid such as SPM may be supplied to the lower surface and the end surface of the substrate W, or may be supplied to the upper surface, the lower surface, and the end surface of the substrate W. In this case, the sulfuric acid-containing liquid may be discharged from the lower surface nozzle 35.

The sulfuric acid and the hydrogen peroxide water may be mixed outside the chemical liquid nozzle 27 instead of inside the chemical liquid nozzle 27. For example, the sulfuric acid and the hydrogen peroxide water may be mixed in the piping and then supplied to the chemical liquid nozzle 27. In this case, the sulfuric acid and the hydrogen peroxide water may be mixed in the chamber 12 or may be mixed outside the chamber 12.

When the temperature difference between the sulfuric acid-containing liquid such as SPM and the replacement liquid such as hydrogen peroxide water is small, the supply of the replacement liquid to the substrate W may be started in the first closed state or the second closed state.

The rotational speed of the substrate W when the supply of the replacement liquid to the substrate W is started may be equal to or lower than the rotational speed of the substrate W when the sulfuric acid-containing liquid such as SPM is supplied to the substrate W.

The plurality of first chuck pins 22a and the plurality of second chuck pins 22b may be switched between two of the fully closed state, the first closed state, and the second closed state while the rotational speed of the substrate W increases or decreases.

Instead of supplying the sulfuric acid-containing liquid such as the SPM to the substrate W to which the liquid is not attached, the sulfuric acid-containing liquid may be supplied to the substrate W to which the liquid is attached. In this way, since the heat of the sulfuric acid-containing liquid is also transmitted to the liquid attached to the substrate W, the rate at which the temperature of the substrate W rises can be reduced.

The number of chuck pins 22 in contact with the end surface of the substrate W may be changed not only when the sulfuric acid-containing liquid such as SPM is supplied to the substrate W, but also when a liquid other than the sulfuric acid-containing liquid such as the hydrogen peroxide water, hot water, or rinse liquid is supplied to the substrate W.

As long as the gripping portion 63g has a shape extending in the circumferential direction of the substrate W along the end surface of the substrate W, the number of the plurality of first chuck pins 22a may be two instead of three or more. Similarly, as long as the gripping portion 63g has a shape extending in the circumferential direction of the substrate W along the end surface of the substrate W, the number of the plurality of second chuck pins 22b may be two instead of three or more. For example, when the substrate W is circular, the number of at least one of the plurality of first chuck pins 22a and the plurality of second chuck pins 22b may be two as long as the gripping portion 63g has an arc shape along the end surface of the substrate W.

The substrate processing apparatus 1 is not restricted to an apparatus to process a disc-shaped substrate W, and may be an apparatus to process a polygonal substrate W.

Two or more arrangements among all the arrangements described above may be combined. Two or more steps among all the steps described above may be combined.

The embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

### REFERENCE SIGNS LIST

1: Substrate processing apparatus, 2: Processing unit, 3: Controller, 3a: Computer main body, 3b: CPU, 3c: Memory, 3d: Peripheral device, 3e: Storage, 3f: Reader, 3g: Communication device, 4: Transfer passage, 5: Transfer system, 6: Relay base, 6L: Lower relay base, 6u: Upper relay base, 7: Non-processed relay base, 8: Processed relay base, 11: FFU, 12: Chamber, 13: Partition wall, 13a: Air blowing port, 13b: Carry-in/carry-out port, 17: Shutter, 18: Rectifying plate, 21: Spin chuck, 22: Chuck pin, 22a: First chuck pin, 22b: Second chuck pin, 23: Spin base, 24: Spin shaft, 25: Electric motor, 26: Chuck housing, 27: Chemical liquid nozzle, 28f: Flow control valve, 28p: Sulfuric acid piping, 28v: Sulfuric acid valve, 29f: Flow control valve, 29p: Hydrogen peroxide water piping, 29v: Hydrogen peroxide water valve, 30: First nozzle moving unit, 31: Rinse liquid nozzle, 32p: Pure water piping, 32v: Pure water valve, 33h: Heater, 33p: Hot water piping, 33v: Hot water valve, 34: Second nozzle moving unit, 35: Lower surface nozzle, 36p: Rinse liquid piping, 36v: Rinse liquid valve, 41: Processing cup, 42: Cylindrical outer wall, 43: Cup, 44: Guard, 44u: Upper end, 45: Circular cylindrical portion, 46: Ceiling portion, 47: Guard raising/lowering unit, 48: Partitioning plate, 49: Exhaust duct, 49u: Upstream end, 51: Sulfuric acid supply system, 52: Sulfuric acid tank, 53: Circulation piping, 53c: Common piping, 531: Individual piping, 54d: Downstream heater, 54u: Upstream heater, 55: Circulation pump, 56: Concentration meter, 57: Flowmeter, 58p: Return piping, 58v: Return valve, 61a: First actuator, 61b: Second actuator, 62a: First power transmission path, 62b: Second power transmission path, 63g: Gripping portion, 63s: Supporting portion, A1: Rotational axis, A2: Rotational axis, CA: Carrier, CC: Cabinet, CR: Center robot, CRL: Lower center robot, CRu: Upper center robot, FB: Fluid box, Hc: Hand, Hi: Hand, IR: Indexer robot, LP: Load port, P: Program, RM: Removable medium, S1~S6: Step, SL: Lower space, Su: Upper space, T1: First chemical liquid supplying time, T2: Second chemical liquid supplying time, T4: Fourth chemical liquid supplying time, T3: Third chemical liquid supplying time, T5: Fifth chemical liquid supplying time, T6: Replacement liquid supplying time, T7: Rinse liquid supplying time, T8: Rinse liquid supplying time, TW: Tower, W: Substrate, X: First rotational speed, Y: Second rotational speed

1. A substrate processing method, comprising:
starting and continuing supply of a sulfuric acid-containing liquid having a temperature higher than that of a horizontal substrate to the substrate while rotating the substrate in a fully closed state where a plurality of first chuck pins and a plurality of second chuck pins are in contact with an end surface of the substrate;
supplying the sulfuric acid-containing liquid to the substrate while rotating the substrate in a first closed state where the plurality of first chuck pins are in contact with the end surface of the substrate and the plurality of second chuck pins are separated from the end surface of the substrate by separating the plurality of second chuck pins from the end surface of the substrate;
supplying the sulfuric acid-containing liquid to the substrate while rotating the substrate in the fully closed state by bringing the plurality of second chuck pins into contact with the end surface of the substrate; and
supplying the sulfuric acid-containing liquid to the substrate while rotating the substrate in a second closed state where the plurality of first chuck pins are separated from the end surface of the substrate and the plurality of second chuck pins are in contact with the end surface of the substrate by separating the plurality of first chuck pins from the end surface of the substrate.

2. The substrate processing method according to claim 1, further comprising:
supplying the sulfuric acid-containing liquid to the substrate while rotating the substrate in the fully closed state by bringing the plurality of first chuck pins into contact with the end surface of the substrate; and
replacing the sulfuric acid-containing liquid in contact with the substrate with a replacement liquid having a temperature lower than that of the sulfuric acid-containing liquid while rotating the substrate in the fully closed state.

3. The substrate processing method according to claim 2, wherein a rotational speed of the substrate when the sulfuric acid-containing liquid in contact with the substrate is started to be replaced with the replacement liquid is higher than a rotational speed of the substrate in at least one of starting and continuing the supply of the sulfuric acid-containing liquid to the substrate while rotating the substrate in the fully closed state, supplying the sulfuric acid-containing liquid to the substrate while rotating the substrate in the first closed state, supplying the sulfuric acid-containing liquid to the substrate while rotating the substrate in the fully closed state and supplying the sulfuric acid-containing liquid to the substrate while rotating the substrate in the second closed state.

4. The substrate processing method according to claim 2, wherein the replacement liquid is hydrogen peroxide water having a temperature lower than that of the sulfuric acid-containing liquid.

5. The substrate processing method according to claim 2, wherein starting and continuing the supply of the sulfuric acid-containing liquid to the substrate while rotating the substrate in the fully closed state, supplying the sulfuric acid containing liquid to the substrate while rotating the substrate in the first closed state, supplying the sulfuric acid-containing liquid to the substrate while rotating the substrate in the fully closed state and supplying the sulfuric acid-containing liquid to the substrate while rotating the substrate in the second closed state are performed again after the sulfuric acid-containing liquid in contact with the substrate is replaced with the replacement liquid.

6. The substrate processing method according to claim 1, wherein at least one of switching from starting and continuing the supply of the sulfuric acid-containing liquid to the substrate while rotating the substrate in the fully closed state to supplying the sulfuric acid-containing liquid to the substrate while rotating the substrate in the first closed state, switching from supplying the sulfuric acid-containing liquid to the substrate while rotating the substrate in the first closed state to supplying the sulfuric acid-containing liquid to the substrate while rotating the substrate in the fully closed state, and switching from supplying the sulfuric acid-containing liquid to the substrate while rotating the substrate in the fully closed state to supplying the sulfuric acid-containing liquid to the substrate while rotating the substrate in the second closed state is performed while maintaining a constant rotational speed of the substrate.

7. The substrate processing method according to claim 6, wherein at least one of switching from starting and continuing the supply of the sulfuric acid-containing liquid to the substrate while rotating the substrate in the fully closed state to supplying the sulfuric acid-containing liquid to the substrate while rotating the substrate in the first closed state and switching from supplying the sulfuric acid-containing liquid to the substrate wi rotating the substrate in the fully closed state to supplying the sulfuric acid-containing liquid to the substrate while rot substrate in the second closed state is performed while maintaining a constant rotational speed of the substrate.

8. The substrate processing method according to claim 1, wherein starting and continuing the supply of the sulfuric acid-containing liquid to the substrate while rotating the substrate in the fully closed state includes starting supply of the sulfuric acid-containing liquid to the substrate while rotating the substrate in a state where the plurality of first chuck pins and the plurality of second chuck pins are in contact with the end surface of the substrate and the liquid is not in contact with the substrate.

9. The substrate processing method according to claim 1, wherein a period of starting and continuing the supply of the sulfuric acid-containing liquid to the substrate while rotating the substrate in the fully closed state is shorter than a period of supplying the sulfuric acid-containing liquid to the substrate while rotating the substrate in the first closed state and shorter than a period of supplying the sulfuric acid-containing liquid to the substrate while rotating the substrate in the second closed state.

10. The substrate processing method according to claim 1, wherein a period of starting and continuing the supply of the sulfuric acid-containing liquid to the substrate while rotating the substrate in the fully closed state is longer than a period of supplying the sulfuric acid-containing liquid to the substrate while rotating the substrate in the fully closed state.

11. A substrate processing apparatus, comprising:
a plurality of first chuck pins that hold a horizontal substrate by coming into contact with an end surface of the substrate;
a plurality of second chuck pins that hold the substrate by coming into contact with the end surface of the substrate;
a first actuator that moves each of the plurality of first chuck pins between an open position where the first chuck pin is separated from the end surface of the substrate and a closed position where the first chuck pin is in contact with the end surface of the substrate;
a second actuator that moves each of the plurality of second chuck pins between an open position where the second chuck pin is separated from the end surface of the substrate and a closed position where the second chuck pin is in contact with the end surface of the substrate;
an electric motor that rotates the substrate held by at least one of the plurality of first chuck pins and the plurality of second chuck pins;
a nozzle that supplies a sulfuric acid-containing liquid having a temperature higher than that of the substrate to the substrate held by at least one of the plurality of first chuck pins and the plurality of second chuck pins;
a valve that switches between a supply execution state where the supply of the sulfuric acid-containing liquid to the nozzle is performed and a supply stop state where the supply of the sulfuric acid-containing liquid to the nozzle is stopped; and
a controller that controls the first actuator, the second actuator, an electric motor, and a valve,
wherein the controller executes:
starting and continuing supply of the sulfuric acid-containing liquid to the substrate while rotating the substrate in a fully closed state where the plurality of first chuck pins and the plurality of second chuck pins are in contact with the end surface of the substrate;
supplying the sulfuric acid-containing liquid to the substrate while rotating the substrate in a first closed state where the plurality of first chuck pins are in contact with the end surface of the substrate and the plurality of second chuck pins are separated from the end surface of the substrate by separating the plurality of second chuck pins from the end surface of the substrate;
supplying the sulfuric acid-containing liquid to the substrate while rotating the substrate in the fully closed state by bringing the plurality of second chuck pins into contact with the end surface of the substrate; and
supplying the sulfuric acid-containing liquid to the substrate while rotating the substrate in a second closed state where the plurality of first chuck pins are separated from the end surface of the substrate and the plurality of second chuck pins are in contact with the end surface of the substrate by separating the plurality of first chuck pins from the end surface of the substrate.
